(19) United States
(12) Patent Application Publication
(10) Pub. No.: US 2025/0331396 A1
(43) Pub. Date: Oct. 23, 2025

(54) RESIN COMPOSITION, ADHESIVE MEMBER, AND DISPLAY DEVICE INCLUDING THE ADHESIVE MEMBER

(71) Applicant: Samsung Display Co., Ltd., Yongin-si (KR)

(72) Inventor: Koki IKUTA, Yokohama (JP)

(21) Appl. No.: 19/030,916

(22) Filed: Jan. 17, 2025

(30) Foreign Application Priority Data
Apr. 18, 2024 (KR) 10-2024-0051887

(51) Int. Cl. H10K 59/80; B32B 7/12; B32B 17/06; C09J 7/38; C09J 11/08

(52) U.S. Cl. CPC H10K 59/873; B32B 7/12; B32B 17/06; C09J 7/385; C09J 11/08; B32B 2255/26; B32B 2307/748; B32B 2457/208; C09J 2203/326; C09J 2301/312; C09J 2301/414

(57) ABSTRACT

A resin composition that includes at least one monofunctional (meth)acrylate monomer, an organopolysiloxane, and at least one photoinitiator including a radical polymerization initiator is provided. The resin composition may have a shear viscosity of about 5 mPa·s to about 50 mPa·s as measured at a temperature of about 25° C., a storage modulus of about 1 MPa or less as measured by dynamic viscoelasticity measurement in a shear mode at a frequency of about 1 Hz and at a temperature of about −20° C. once photocured, and a loss tangent (tan δ) of about 2.0 or more as measured by the dynamic viscoelasticity measurement once photocured, and may be optically transparent once photocured.

### CROSS-REFERENCE TO RELATED APPLICATION

This application claims priority to and the benefit of Korean Patent Application No. 10-2024-0051887, filed on Apr. 18, 2024, in the Korean Intellectual Property Office, the entire content of which is incorporated herein by reference.

### BACKGROUND

### 1. Field

One or more aspects of embodiments of the present disclosure relate to a resin composition including an organopolysiloxane, an adhesive member made from the resin composition, and a display device including the adhesive member.

### 2. Description of the Related Art

Various display devices used for multimedia apparatuses, such as televisions, mobile phones, tablet computers, navigation units, game consoles, and/or the like, are currently undergoing vigorous development. In particular, recent advancements focus on display devices that can be folded, bent, rolled, and/or the like, incorporating flexible display members (components) that can be bent to enhance portability and user convenience. Adhesive resins used to form adhesive layers on (applied to) display devices of various shapes (types) are desired (or required) to have excellent or suitable coatability for different (members (components) of different) types (kinds) of display devices.

### SUMMARY

One or more aspects of embodiments of the present disclosure are directed toward a resin composition, which exhibits a low-viscosity characteristics before curing and exhibits low elastic modulus and high adhesion after curing, an adhesive member made from the resin composition, and a display device including the adhesive member.

Additional aspects will be set forth in part in the description which follows and, in part, will be apparent from the description, or may be learned by practice of the presented embodiments of the disclosure.

One or more embodiments of the present disclosure provides a resin composition including at least one monofunctional (meth)acrylate monomer, an organopolysiloxane, and at least one photoinitiator including a radical polymerization initiator. The resin composition may have a shear viscosity of about 5 millipascal second (mPa·s) to about 50 mPa·s as measured at a temperature of about 25° C. according to JIS Z8803, a storage modulus of (e.g., at most) about 1 megapascal (MPa) or less as measured by a dynamic viscoelasticity measurement in a shear mode at a frequency of about 1 hertz (Hz) and at a temperature of about −20° C. after photocuring (e.g., once photocured). The resin composition may have a loss tangent (tan δ) of (e.g., at least) about 2.0 or more as measured by the dynamic viscoelasticity measurement in the shear mode at the frequency of about 1 Hz and at the temperature of about −20° C. after the photocuring (e.g., once photocured), and may be optically transparent after the photocuring (e.g., once photocured).

In one or more embodiments, an amount of the organopolysiloxane may be (e.g., at least) about 5 wt % or more and less than (e.g., at most) about 35 wt % based on a total of 100 wt % of the resin composition.

In one or more embodiments, a weight average molecular weight of the organopolysiloxane may be (e.g., at least) about 500 or more and less than (e.g., at most) about 50,000.

In one or more embodiments, the organopolysiloxane may not include a (e.g., may exclude any) radical polymerizable group.

In one or more embodiments, the resin composition may have a 180° peel strength of (e.g., at least) about 300 gram force per 25 millimeter (gf/25 mm) or more for at least one of a polymer substrate or a glass substrate at a temperature of about 25° C. after the photocuring (e.g., once photocured).

In one or more embodiments, the resin composition may not include a (e.g., may exclude any) solvent.

In one or more embodiments, the monofunctional (meth)acrylate monomer may include at least one of (e.g., selected from among) 4-hydroxybutyl acrylate (4-HBA), 2-ethylhexyl acrylate (2-EHA), tetrahydrofurfuryl acrylate (THF-A), or 2-ethylhexyl-diglycol acrylate (EHDG-AT).

In one or more embodiments, an amount of the monofunctional (meth)acrylate monomer may be about 60 wt % to about 85 wt % based on a total of 100 wt % of the resin composition.

In one or more embodiments, the resin composition may further include a urethane (meth)acrylate oligomer.

In one or more embodiments, the resin composition may further include a silane coupling agent.

In one or more embodiments, the resin composition may have a glass transition temperature of about −46° C. to about −39° C. after the photocuring (e.g., once photocured).

In one or more embodiments, the resin composition may be provided by an inkjet printing method or a dispensing method.

In one or more embodiments of the present disclosure, an adhesive member may have a storage modulus of (e.g., at most) about 1 MPa or less as measured by a dynamic viscoelasticity measurement in a shear mode at a frequency of about 1 Hz and at a temperature of about −20° C. The adhesive member may have a loss tangent (tan δ) of (e.g., at least) about 2.0 or more as measured by the dynamic viscoelasticity measurement in a shear mode at a frequency of about 1 Hz and at a temperature of about −20° C., may be optically transparent, and may include a polymer derived from a resin composition. The resin composition may include at least one monofunctional (meth)acrylate monomer, an organopolysiloxane, and at least one photoinitiator including a radical polymerization initiator, and the resin composition may have a shear viscosity of about 5 mPa·s to about 50 mPa·s as measured at a temperature of about 25° C. according to JIS Z8803.

In one or more embodiments, the adhesive member may have a 180° peel strength of (e.g., at least) about 300 gf/25 mm or more for at least one of a polymer substrate or a glass substrate at a temperature of about 25° C.

In one or more embodiments, the adhesive member may have a glass transition temperature of about −46° C. to about −39° C.

In one or more embodiments of the present disclosure, an electronic device may include a display panel, a window arranged on the display panel, and an adhesive member, which has a storage modulus of (e.g., at most) about 1 MPa or less as measured by a dynamic viscoelasticity measurement in a shear mode at a frequency of about 1 Hz and at a temperature of about −20° C. The adhesive member may have a loss tangent (tan δ) of (e.g., at least) about 2.0 or more as measured by the dynamic viscoelasticity measurement in the shear mode at the frequency of about 1 Hz and at the temperature of about −20° C., may be optically transparent. The adhesive member may include a polymer derived from a resin composition, and may be arranged between the display panel and the window. The resin composition may include at least one monofunctional (meth)acrylate monomer, an organopolysiloxane, and at least one photoinitiator including a radical polymerization initiator, and the resin composition may have a shear viscosity of about 5 mPa·s to about 50 mPa·s as measured at a temperature of about 25° C. according to JIS Z8803.

In one or more embodiments, the electronic device may further include an input sensing part arranged between the display panel and the window, and the adhesive member may be arranged between the display panel and the input sensing part, or between the input sensing part and the window.

### BRIEF DESCRIPTION OF THE DRAWINGS

The accompanying drawings are included to provide a further understanding of the preceding, (among other aspects, features, and advantages of certain embodiments of the disclosure) and are incorporated in and constitute a part of this specification. The drawings illustrate example embodiments of the present disclosure and, together with the description, serve to explain principles of the present disclosure. In the drawings:

FIG. 1A is a perspective view illustrating a display device according to one or more embodiments;

FIG. 1B is a perspective view illustrating a display device according to one or more embodiments;

FIG. 1C is a plan view illustrating a display device according to one or more embodiments;

FIG. 1D is a perspective view illustrating a display device according to one or more embodiments;

FIG. 2 is an exploded perspective view illustrating a display device according to one or more embodiments;

FIG. 3 is a cross-sectional view illustrating a portion corresponding to line I-I′ in FIG. 2;

FIG. 4 is a cross-sectional view illustrating a portion of a display device according to one or more embodiments;

FIG. 5A is a schematic view illustrating a method for manufacturing an adhesive member according to one or more embodiments;

FIG. 5B is a schematic view illustrating a method for manufacturing an adhesive member according to one or more embodiments;

FIG. 5C is a schematic view illustrating a method for manufacturing an adhesive member according to one or more embodiments;

FIG. 5D is a schematic view illustrating a method for manufacturing an adhesive member according to one or more embodiments;

FIG. 6A is a schematic view illustrating a method for manufacturing an adhesive member according to one or more embodiments;

FIG. 6B is a schematic view illustrating a method for manufacturing an adhesive member according to one or more embodiments;

FIG. 6C is a schematic view illustrating a method for manufacturing an adhesive member according to one or more embodiments;

FIG. 7 is a cross-sectional view illustrating a display device according to one or more embodiments; and

FIG. 8 is a cross-sectional view illustrating a display device according to one or more embodiments.

### DETAILED DESCRIPTION

Reference will now be made in more detail to one or more embodiments of the present disclosure, which may be modified in one or more suitable forms. Particular embodiments thereof will be illustrated in the drawings and described herein in more detail. In this regard, the present embodiments may have different forms and should not be construed as limited to one or more embodiments set forth herein. Rather, these embodiments are provided so that this disclosure will be thorough and complete, and will fully convey the scope of the present disclosure to those skilled in the art. Accordingly, one or more embodiments are merely described in more detail, by referring to the drawings, to explain aspects of the present description.

It will be understood that in this specification, when an element (or region, layer, section, and/or the like) is referred to as being “on”, “connected to” or “coupled to” another element, it can be arranged directly on, connected or coupled to the other element or a third element may be arranged between the elements.

Like reference numbers or symbols refer to like elements throughout, and duplicative descriptions thereof may not be provided. In some embodiments, in the drawings, the thickness, the ratio, and the dimension of elements are exaggerated for effective description of the technical contents. The term “and/or” includes one or more combinations which may be defined by relevant elements.

It will be understood that, although the terms first, second, and/or the like may be used herein to describe one or more suitable elements, these elements should not be limited by these terms. These terms are only used to distinguish one element from another element. For example, a first element could be termed a second element without departing from the teachings of disclosure, and similarly, a second element could be termed a first element. As used herein, expressions utilized in the singular form, such as “a,” “an,” and “the”, are intended to include the plural forms as well, unless the context clearly indicates otherwise.

In some embodiments, spatially relative terms, such as “below”, “beneath”, “on”, “above”, and/or the like, are used for explaining the relation of elements shown in the drawings. It will be understood that the spatially relative terms are relative concepts that are explained based on the direction shown in the drawing, and are also intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Because the disclosure may have diverse modified embodiments, the embodiments are illustrated in the drawings and are described in the detailed description. An aspect and a characteristic of the disclosure, and a method of accomplishing these will be apparent if (e.g., when) referring to one or more embodiments described with reference to the drawings. The disclosure may, however, be embodied in many different forms and should not be construed as limited to the embodiments set forth herein.

It will be further understood that the terms such as “includes”, “include”, including”, “has”, “have”, “having”, “comprises”, “comprising,” and/or “comprise,” when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including chemical, technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this context, “consisting essentially of” indicates that any additional components will not materially affect the chemical, physical, optical or electrical properties of the semiconductor film.

Further, in this specification, the phrase “on a plane,” or “plan view,” indicates viewing a target portion from the top, and the phrase “on a cross-section” indicates viewing a cross-section formed by vertically cutting a target portion from the side.

### Display Device

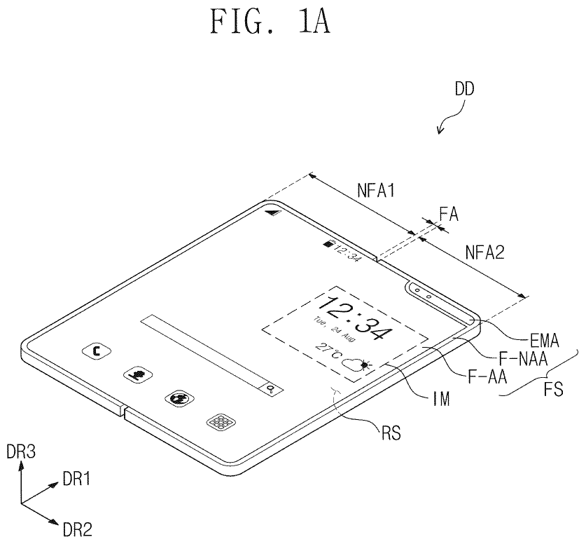

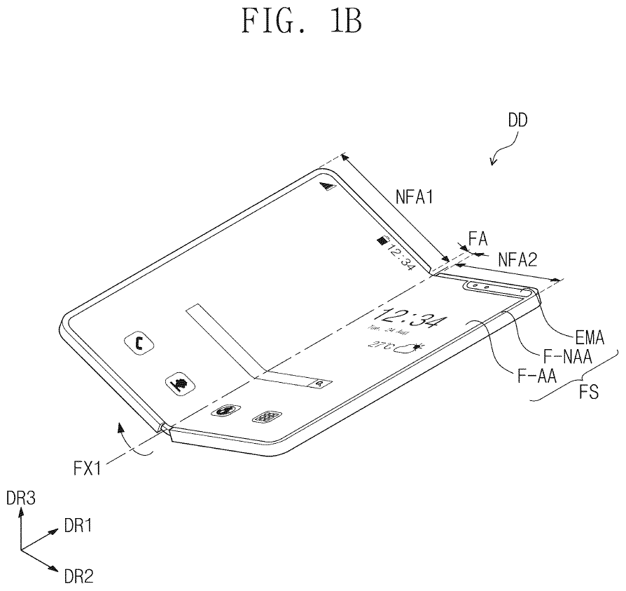

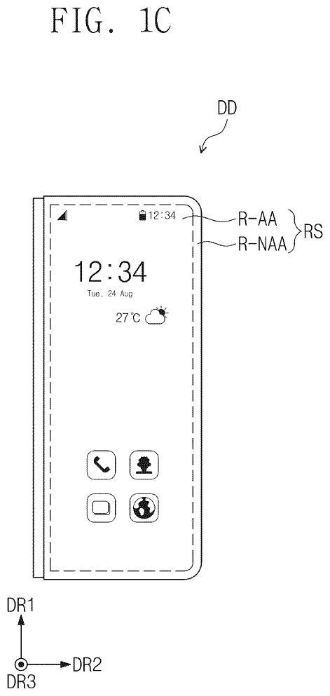

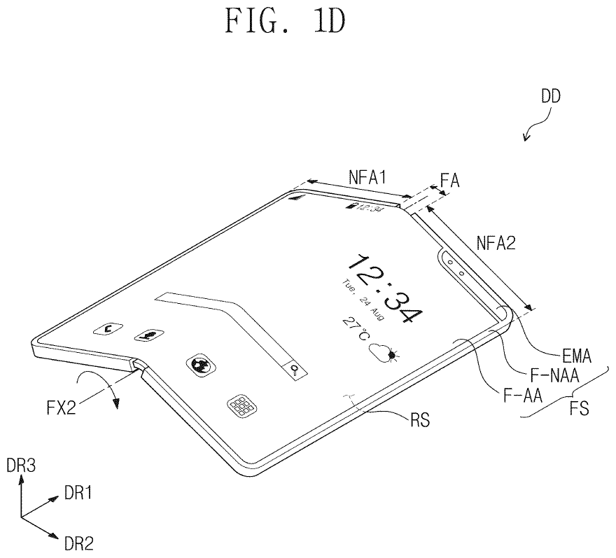

Hereinafter, an adhesive member and a display device including the same according to one or more embodiments of the disclosure will be described with reference to the accompanying drawings. FIG. 1A is a perspective view of a spread state of a display device DD according to one or more embodiments.

The display device DD according to one or more embodiments may be a device that is activated in response to an electrical signal. For example, the display device DD may be a mobile phone, a tablet computer, a vehicle navigation unit, a game console, a wearable device, and/or the like, but one or more embodiments is not limited thereto. FIG. 1A and/or the like illustrate a mobile phone as an example of the display device DD. In this specification, an electronic device may be the display device DD or may include the display device DD.

The display device DD may include a first display surface FS defined by a plane including a first directional axis DR1 and a second directional axis DR2 crossing the first directional axis DR1. The display device DD may provide an image IM for a user through the first display surface FS. The display device DD may display the image IM in a third directional axis DR3 that passes through the first display surface FS and has a normal (perpendicular) orientation to each of the first directional axis DR1 and the second directional axis DR2.

In the present disclosure, the first directional axis DR1 and the second directional axis DR2 may perpendicularly cross each other, and the third directional axis DR3 may have an orientation that is normal (perpendicular) to a plane defined by the first directional axis DR1 and the second directional axis DR2. A thickness direction of the display device DD may be a direction parallel to the third directional axis DR3. A front surface (or top surface) and a rear surface (or bottom surface) may oppose each other with respect to the third directional axis DR3, and a normal direction to each of the front surface (or top surface) and the rear surface (or bottom surface) may be parallel to the third directional axis DR3. The front surface (or top surface) refers to a surface adjacent to the first display surface FS, and the rear surface (or bottom surface) refers to a surface spaced and/or apart (e.g., spaced apart or separated) from the first display surface FS. In some embodiments, the rear surface (or bottom surface) refers to a surface close to a second display surface RS to be described in more detail later. An upper side refers to a direction that is close to the first display surface FS, and a lower side refers to a direction that is away from the first display surface FS.

A cross-section refers to a surface defined by a plane with an orientation that is parallel to a thickness direction DR3, and a plane refers to a surface defined by a plane with an orientation that is normal (e.g., perpendicular) to the thickness direction DR3. The plane may be defined by the first directional axis DR1 and the second directional axis DR2. A plan view refers to a view looking down from above, showing the layout of the surface defined by the plane described herein. A cross-sectional view refers to a view in a direction parallel to either the first directional axis DR1 or the second directional axis DR2, and typically shows the internal structure and members (components) in a cross-section that is normal (perpendicular) to the thickness direction DR3.

Directions indicated by the first to third directional axes DR1, DR2 and DR3 used herein are relative concepts, and may be changed to other directions. In some embodiments, the directions indicated by the first to third directional axes DR1, DR2 and DR3 may be referred to as first to third directions, and may be designated by like reference numbers or symbols.

The display device DD may detect an external input applied from the outside. The external input may include one or more suitable types (kinds) of inputs provided from the outside of the display device DD. For example, the external input may include not only a touch by part of the body, such as a user's hand, but also an external input (e.g., hovering) applied by approaching the display device DD or being adjacent thereto by a set or predetermined distance. In some embodiments, the external input may include one or more suitable types (kinds) such as force, pressure, temperature, and light.

The display device DD may include the first display surface FS and the second display surface RS. The first display surface FS may include a first active area F-AA, a first peripheral area F-NAA, and an electronic module area EMA. The second display surface RS may be defined as a surface opposing at least a portion of the first display surface FS. For example, the second display surface RS may be defined as one portion of a rear surface of the display device DD.

The first active area F-AA may be an area that is activated in response to an electrical signal. The first active area F-AA may be an area on which the image IM is displayed, and which is capable of detecting one or more suitable types (kinds) of external inputs.

The first peripheral area F-NAA may be adjacent to the first active area F-AA. The first peripheral area F-NAA may have a set or predetermined color. The first peripheral area F-NAA may be around (e.g., surround) the first active area F-AA. Accordingly, a shape of the first active area F-AA may be substantially defined by the first peripheral area F-NAA. However, this is merely an example (e.g., illustrative), and the first peripheral area F-NAA may be arranged adjacent to only one side of the first active area F-AA, or may not be provided.

Various electronic modules may be arranged on the electronic module area EMA. For example, the electronic modules may include at least one of a camera, a speaker, a light detecting sensor, a heat detecting sensor, and/or the like. The electronic module area EMA may detect an external subject received through the display surfaces FS and RS, or provide a sound signal such as voice, to the outside through the display surfaces FS and RS. The electronic module may include a plurality of components, and is not limited to any one or more embodiments.

The electronic module area EMA may be surrounded by the first peripheral area F-NAA. However, this is illustrative, and the electronic module area EMA is not limited to any one or more embodiments. For example, the electronic module area EMA may be surrounded by the first active area F-AA and the first peripheral area F-NAA, and the electronic module area EMA may be arranged within the first active area F-AA.

The display device DD according to one or more embodiments may be a flexible display device. The display device DD according to one or more embodiments may include at least one folding area FA, and a plurality of non-folding areas NFA1 and NFA2 each extending from the folding area FA. For example, a first non-folding area NFA1, the folding area FA, and a second non-folding area NFA2 may be defined in a second direction DR2. The display device DD according to one or more embodiments may include the first non-folding area NFA1 and the second non-folding area NFA2 which are spaced and/or apart (e.g., spaced apart or separated) from each other in the second direction DR2 with the folding area FA therebetween. For example, the first non-folding area NFA1 may be arranged at one side of the folding area FA in the second direction DR2, and the second non-folding area NFA2 may be arranged at the other side of the folding area FA in the second direction DR2.

FIG. 1A and/or the like illustrate one or more embodiments of the display device DD including one folding area FA. However, one or more embodiments is not limited thereto, and a plurality of folding areas may be defined in the display device DD. For example, the display device according to one or more embodiments may include two or more folding areas, and three or more non-folding areas arranged with each of the folding areas therebetween.

FIG. 1B is a perspective view illustrating a folding operation of a display device DD according to one or more embodiments. FIG. 1C is a plan view of a folded state of the display device DD according to one or more embodiments. FIG. 1D is a perspective view illustrating a folding operation of a display device DD according to one or more embodiments.

Referring to FIG. 1B, the display device DD according to one or more embodiments may be folded around a first folding axis FX1 extending in the first direction DR1. In a state in which the display device DD is folded, the folding area FA may have a set or predetermined curvature and a set or predetermined radius of curvature. The display device DD may be folded around the first folding axis FX1 to be changed into an in-folded state so that the first non-folding area NFA1 and the second non-folding area NFA2 face each other, and the first display surface FS is not exposed to the outside.

Referring to FIG. 1C, in the display device DD according to one or more embodiments, the second display surface RS may be visible to a user in the in-folded state. Here, the second display surface RS may include a second active area R-AA that displays an image. The second active area R-AA may be an area that is activated in response to an electrical signal. The second active area R-AA may be an area on which an image is displayed, and which is capable of detecting one or more suitable types (kinds) of external inputs.

The second peripheral area R-NAA may be adjacent to the second active area R-AA. The second peripheral area R-NAA may have a set or predetermined color. The second peripheral area R-NAA may be around (e.g., surround) the second active area R-AA. Although not illustrated, the second display surface RS of the display device DD may also further include an electronic module area on which an electronic module including one or more suitable components is arranged, and the display device DD is not limited to any one or more embodiments.

Referring to FIG. 1D, the display device DD according to one or more embodiments may be folded around a second folding axis FX2 extending in the first direction DR1. The display device DD may be folded around the second folding axis FX2 to be changed into an out-folded state so that the first display surface FS is exposed to the outside. In one or more embodiments, the display device DD may be provided to repeat an operation from a spreading operation to an in-folding or out-folding operation, or vice versa. However, one or more embodiments of the present disclosure is not limited thereto.

FIGS. 1A to 1D illustrate the operation of folding around the one folding axis FX1 or FX2 as an example, but the number of the folding axis and the number of non-folding areas according thereto are not limited thereto. For example, folding around a plurality of folding axes may be performed so that a portion of the first display surface FS and a portion of the second display surface RS face each other. In some embodiments, the first and second folding axes FX1 and FX2 are illustrated as being parallel to a long side of the display device DD, but one or more embodiments is not limited thereto. For example, the first and second folding axes FX1 and FX2 may be parallel to a short side of the display device DD.

In the display device DD, the first non-folding area NFA1 and the second non-folding area NFA2 may each be defined as a portion having the display surfaces FS and RS parallel to a plane defined by the first directional axis DR1 and the second directional axis DR2 in the folded state as illustrated in FIG. 1C. The folding area FA may be defined as an area between the first non-folding area NFA1 and the second non-folding area NFA2. The folding area FA may include a curved portion that is bent to have a set or predetermined curvature in the folded state.

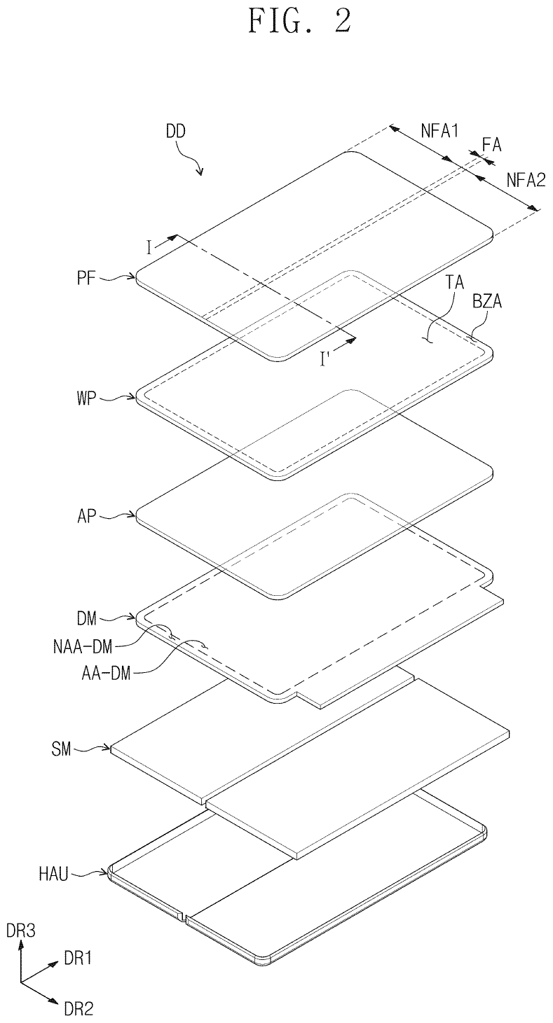

FIG. 2 is an exploded perspective view illustrating a display device DD according to one or more embodiments. Referring to FIG. 2, the display device DD according to one or more embodiments may include a display module DM, a window WP arranged on the display module DM, and an adhesive member AP arranged between the display module DM and the window WP. The display device DD may further include a support member SM arranged below the display module DM, a protective layer PF arranged on the window WP, and a housing HAU that accommodates the display module DM, the support member SM, and/or the like.

The housing HAU may include a material having relatively high rigidity. For example, the housing HAU may include a plurality of frames and/or plates, each of which is made of glass, plastic, and/or metal. The housing HAU may provide a set or predetermined accommodation space. The display module DM may be accommodated in the accommodation space to be protected against an external impact.

The support member SM may include a metal material or a polymer material. For example, the support member SM may be made by including stainless steel, aluminum, and/or an alloy thereof. In one or more embodiments, the support member SM may be made of carbon fiber reinforced plastic (CFRP) and/or the like. However, one or more embodiments is not limited thereto, and the support member SM may include a non-metal material, plastic, glass fiber reinforced plastic, and/or glass. Unlike one or more embodiments illustrated, the support member SM may not be provided.

In one or more embodiments, the display device DD may further include a cushion layer, a shielding layer, and/or the like, which are arranged below the support member SM. The cushion layer may include an elastomer such as a sponge, a foam, and/or a urethane resin. The shielding layer may be an electromagnetic wave shielding layer and/or a heat dissipation layer.

The display module DM may be activated in response to an electrical signal. The display module DM may be activated to display the image IM (see FIG. 1A) on the display surface FS (see FIG. 1A) of the display device DD. A display area AA-DM and a non-display area NAA-DM may be defined in the display module DM. The display area AA-DM may be an area that is activated in response to an electrical signal. The non-display area NAA-DM may be an area that is arranged adjacent to at least one side of the display area AA-DM. A circuit, lines and/or the like for driving the display area AA-DM may be arranged in the non-display area NAA-DM.

The adhesive member AP may be arranged on the display module DM. The display module DM and the window WP may be coupled to each other through the adhesive member AP. The adhesive member AP may be optically transparent. Being optically transparent may refer to that a transmittance of light in a visible light wavelength range is about 80% or more. For example, in the adhesive member AP, a transmittance to light in a wavelength range of about 400 nm to about 800 nm may be about 80% or more.

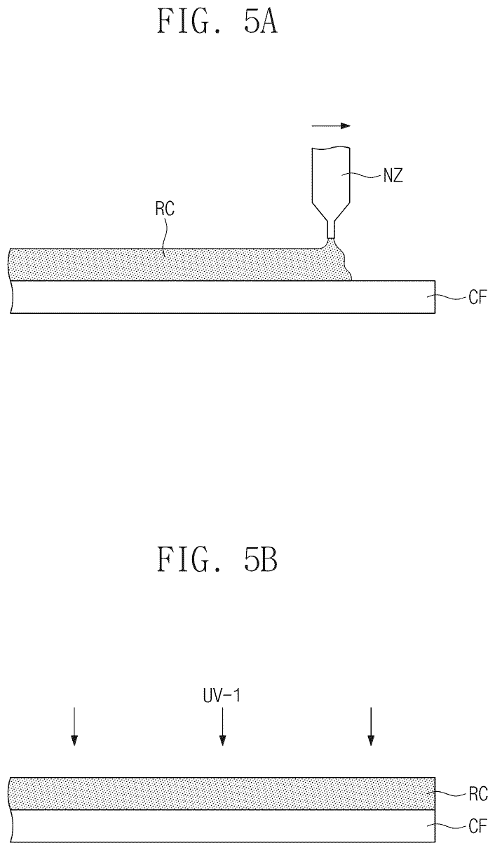

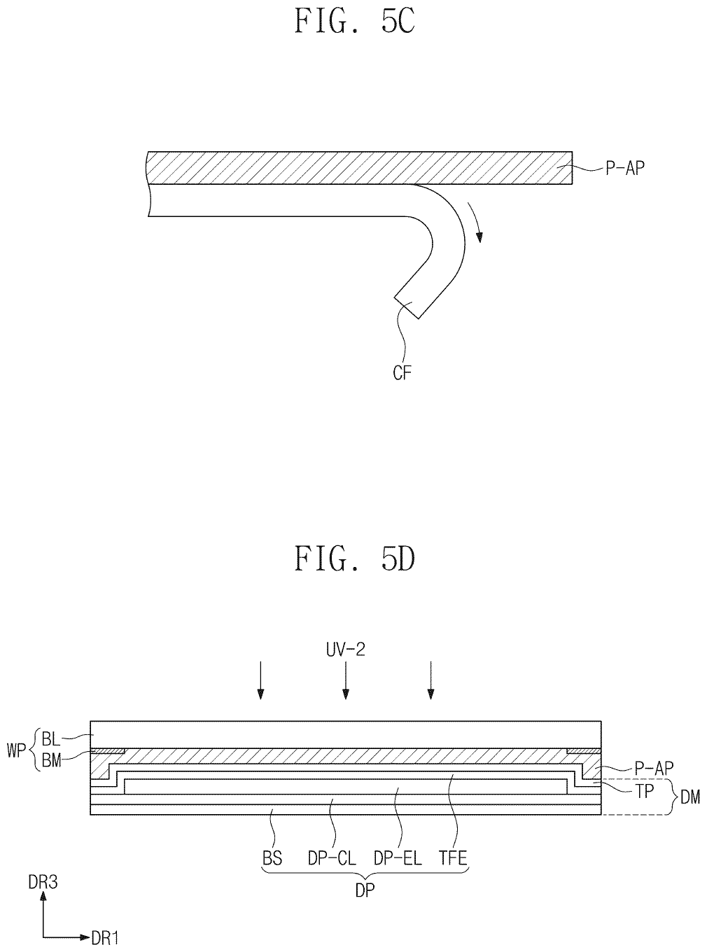

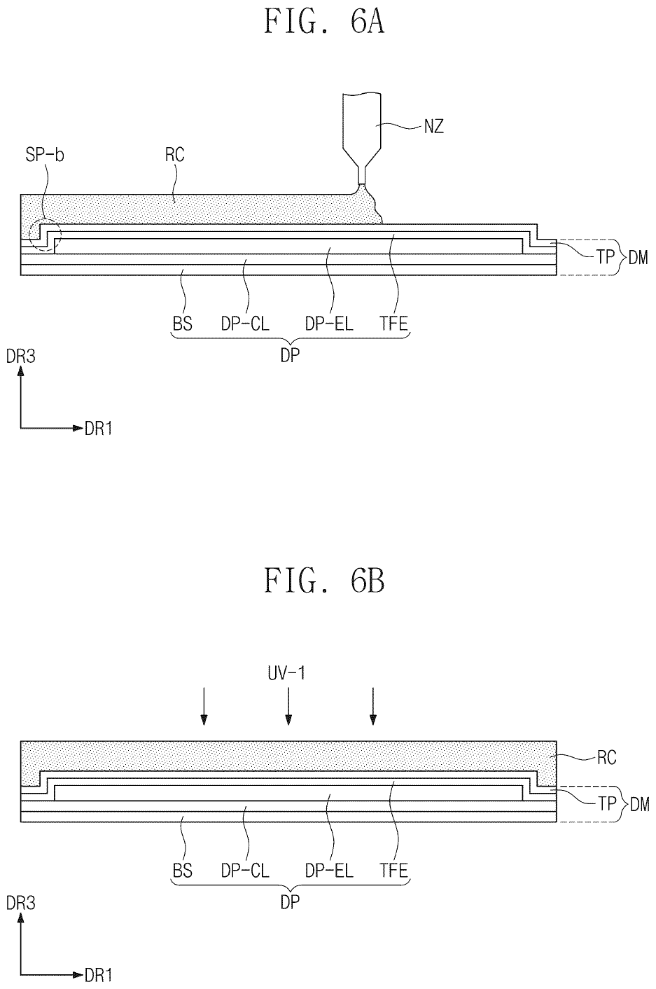

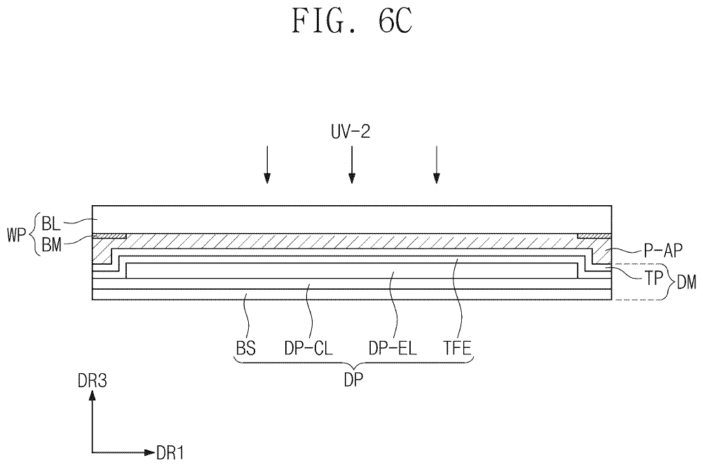

The adhesive member AP according to one or more embodiments may include a polymer derived from a resin composition RC (see FIGS. 5A and 6A) according to one or more embodiments to be described in more detail later. The adhesive member AP may be made from the resin composition RC (see FIGS. 5A and 6A) according to one or more embodiments. The adhesive member AP made from the resin composition RC (see FIGS. 5A and 6A) according to one or more embodiments may exhibit excellent or suitable flexibility and excellent or suitable adhesion. In one or more embodiments, the display device DD including the adhesive member AP made from the resin composition RC (see FIGS. 5A and 6A) may exhibit excellent or suitable reliability.

The window WP may include a glass substrate. The window WP may protect the display module DM and/or the like. The image IM (see FIG. 1A) generated in the display module DM may pass through the window WP to be provided for a user. For example, the window WP may include ultra thin glass (UTG).

The window WP may include a transmission area TA and a bezel area BZA. The transmission area TA may overlap at least a portion of the display area AA-DM of the display module DM. The transmission area TA may be an optically transparent area. The image IM (see FIG. 1A) may be provided for a user through the transmission area TA.

The bezel area BZA may be an area having a relatively low light transmittance compared to the transmission area TA. The bezel area BZA may define a shape of the transmission area TA. The bezel area BZA may be adjacent to the transmission area TA and be around (e.g., surround) the transmission area TA.

The bezel area BZA may have a set or predetermined color. The bezel area BZA may cover the non-display area NAA-DM of the display module DM to prevent or reduce the non-display area NAA-DM from being visible from the outside. However, one or more embodiments is not limited to that illustrated herein. For example, the bezel area BZA may be arranged adjacent to only one side of the transmission area TA, or at least a portion thereof may not be provided.

The protective layer PF may be a functional layer that protects one surface (e.g., top surface) of the window WP. The protective layer PF may include an anti-fingerprint coating agent, a hard coating agent, an antistatic agent, and/or the like. Although not illustrated, an auxiliary adhesive layer may be arranged between the window WP and the protective layer PF. Unlike one or more embodiments illustrated, the protective layer PF may not be provided.

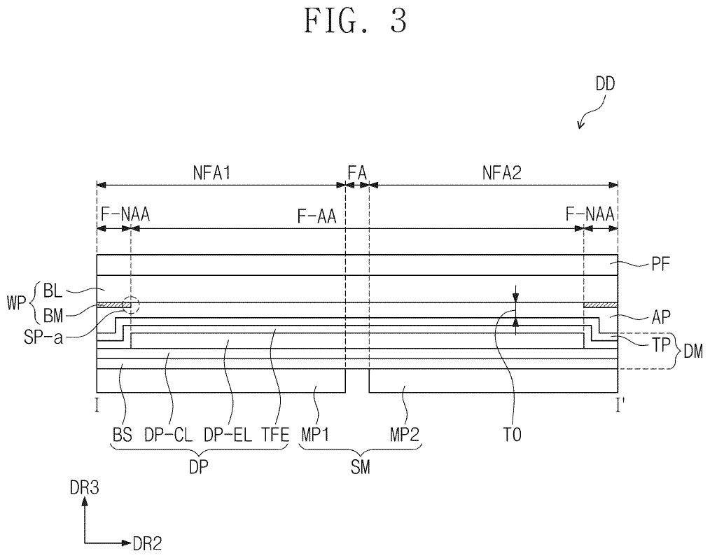

FIG. 3 is a cross-sectional view illustrating a portion corresponding to line I-I′ in FIG. 2. FIG. 3 may be a cross-sectional view illustrating a display device DD according to one or more embodiments. FIG. 3 omits a housing HAU for ease of description, and illustrates a support member SM, a display module DM, an adhesive member AP, a window WP, and a protective layer PF.

Referring to FIG. 3, the support member SM may include a first support MP1 overlapping a first non-folding area NFA1, and a second support MP2 overlapping a second non-folding area NFA2. Each of the first support MP1 and the second support MP2 may be spaced and/or apart (e.g., spaced apart or separated) from a folding area FA. The first support MP1 and the second support MP2 may not overlap the folding area FA. Unlike one or more embodiments illustrated, in some embodiments, at least a portion of the first support MP1 and at least a portion of the second support MP2 may overlap the folding area FA.

The display module DM may include a display panel DP, and an input sensing part TP arranged on the display panel DP. The display panel DP may include a base substrate BS, a circuit layer DP-CL arranged on the base substrate BS, a display element layer DP-EL arranged on the circuit layer DP-CL, and an encapsulating layer TFE that covers the display element layer DP-EL. The adhesive member AP may be arranged between the display panel DP and the window WP.

The components of the display panel DP illustrated in FIG. 3 are illustrative, and the components of the display panel DP are not limited thereto. For example, the display panel DP may include a liquid crystal display element, and in this case, the encapsulating layer TFE may not be provided.

The base substrate BS may provide a base surface on which the circuit layer DP-CL is arranged. The base substrate BS may be a flexible substrate capable of being bent, folded, rolled, and/or the like. The base substrate BS may be a glass substrate, a metal substrate, a polymer substrate, and/or the like. However, one or more embodiments is not limited thereto, and the base substrate BS may include an inorganic layer, an organic layer, and/or a composite material layer.

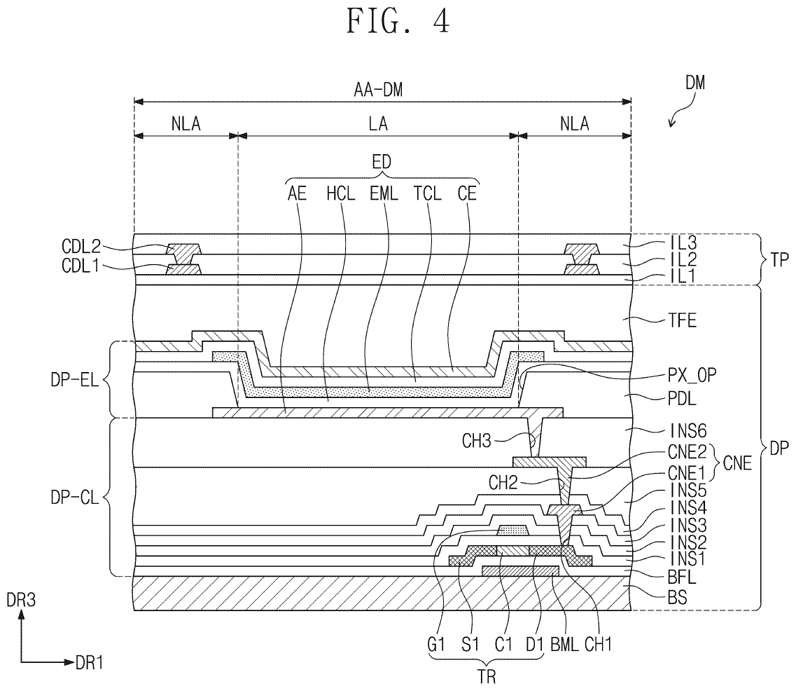

The circuit layer DP-CL may include an insulation layer, a semiconductor pattern, a conductive pattern, a signal line, and/or the like. For example, the circuit layer DP-CL may include a switching transistor and a driving transistor each for driving a light emitting element ED (see FIG. 4) of the display element layer DP-EL.

The display element layer DP-EL may include the light emitting element ED (see FIG. 4) that emits light. For example, the light emitting element ED (see FIG. 4) may include an organic light emitting material, an inorganic light emitting material, an organic-inorganic light emitting material, a quantum dot, a quantum rod, a micro LED, and/or a nano LED.

The encapsulating layer TFE may be arranged on the display element layer DP-EL. The encapsulating layer TFE may protect the display element layer DP-EL from moisture, oxygen, and/or foreign matter such as dust particles. The encapsulating layer TFE may include at least one inorganic layer. The encapsulating layer TFE may include at least one organic layer and/or at least one inorganic layer. For example, the encapsulating layer TFE may include an inorganic layer, an organic layer, and an inorganic layer which are stacked in sequence.

The input sensing part TP may be arranged on the display panel DP. For example, the input sensing part TP may be arranged directly on the encapsulating layer TFE of the display panel DP.

In the present disclosure, if (e.g., when) one component is referred to as being arranged/provided directly on another component, it refers to that a third component is not arranged/provided between the one component and the other component. For example, if (e.g., when) one component is referred to as being “arranged/provided directly” on another component, it refers to that the one component and the other component are in “contact” with each other.

The input sensing part TP may sense an external input to covert the external input into a set or predetermined input signal, and provide the input signal to the display panel DP. For example, in the display device DD according to one or more embodiments, the input sensing part TP may be a touch sensing part that senses a touch. The input sensing part TP may perceive a direct touch by a user, an indirect touch by a user, a direct touch by an object, an indirect touch by an object, and/or the like.

The input sensing part TP may sense at least one of a position of a touch applied from the outside, or an intensity (pressure) of the touch. In one or more embodiments, the input sensing part TP may have one or more suitable structures or be made of one or more suitable materials, and is not limited to any one or more embodiments. For example, the input sensing part TP may sense an external input by using a capacitance method. The display panel DP may receive an input signal from the input sensing part TP, and generate an image corresponding to the input signal.

The window WP may include a base layer BL and a print layer BM. In one or more embodiments, the window WP may further include at least one functional layer provided on the base layer BL. For example, the functional layer may be a hard coating layer, an anti-fingerprint coating layer, and/or the like, but one or more embodiments is not limited thereto.

The base layer BL may be a glass substrate. In one or more embodiments, the base layer BL may be a plastic substrate. For example, the base layer BL may be made of polyimide, polyacrylate, polymethylmethacrylate, polycarbonate, polyethylene naphthalate, polyvinylidene chloride, polyvinylidene difluoride, polystyrene, ethylene vinyl alcohol copolymer, and/or a (e.g., any suitable) combination thereof.

The print layer BM may be arranged on one surface of the base layer BL. The print layer BM may be provided on a bottom surface of the base layer BL, which is adjacent to the display module DM. The print layer BM may be arranged on an edge area of the base layer BL. The print layer BM may be an ink print layer. The print layer BM may be a layer provided by including a pigment or a dye. For example, the print layer BM may be a layer provided by including a black pigment or a black dye. In the window WP, a bezel area BZA may be a portion on which the print layer BM is provided.

A stepped portion SP-a may exist between the print layer BM and a portion of the base layer BL on which the print layer BM is not provided. As the adhesive member AP made from the resin composition RC (see FIGS. 5A and 6A) according to one or more embodiments has excellent or suitable flexibility and excellent or suitable adhesion, the adhesive member AP may be attached to the window WP without being separated from the stepped portion SP-a.

The adhesive member AP may be arranged between the display panel DP and the window WP. The adhesive member AP may be arranged between the input sensing part TP arranged on the display panel DP and the window WP.

The adhesive member AP may have a thickness TO of about 10 micrometer (μm) to about 500 μm, or about 50 μm to about 200 μm. For example, the thickness TO of the adhesive member AP may be about 50 μm to about 100 μm. However, this is illustrative, and the thickness TO of the adhesive member AP is not limited thereto.

In one or more embodiments, the adhesive member AP may have a storage modulus of more than about 0 megapascal (MPa) but at most (e.g., not more than) about 1 MPa as measured by dynamic viscoelasticity measurement in a shear (torsion) mode at a frequency of about 1 hertz (Hz) and at a temperature of about −20° C. For example, the adhesive member AP may have the storage modulus of about 0.04 MPa to about 1 MPa as measured by the dynamic viscoelasticity measurement in the shear (torsion) mode at the frequency of about 1 Hz and at the temperature of about −20° C.

The adhesive member AP, which has the storage modulus of more than about 1 MPa as measured by the dynamic viscoelasticity measurement in the shear (torsion) mode at the frequency of about 1 Hz and at the temperature of about −20° C., may be vulnerable to an external impact and may have very low flexibility, and thus may not be suitable to be used for the display device. In contrast, the adhesive member AP according to one or more embodiments, which has the storage modulus of (e.g., at most) about 1 MPa or less as measured by the dynamic viscoelasticity measurement in the shear (torsion) mode at the frequency of about 1 Hz and at the temperature of about −20° C., may exhibit excellent or suitable impact resistance and excellent or suitable flexibility. In one or more embodiments, the display device DD including the adhesive member AP may exhibit excellent or suitable reliability. For example, an adhesive member with a storage modulus greater than about 1 MPa at −20° C. is likely to be inflexible and vulnerable to external impacts, making it unsuitable for use in a display device. Conversely, an adhesive member with a storage modulus of about 1 MPa or less at −20° C., as described in one or more embodiments, provides better impact resistance and flexibility, and enhances the reliability of a display device included therein.

In one or more embodiments, the adhesive member AP may have a loss tangent (tan δ) of (e.g., at least) about 2.0 or more as measured by the dynamic viscoelasticity measurement in the shear (torsion) mode at the frequency of about 1 Hz and at the temperature of about −20° C. The loss tangent (tan δ) is a ratio (G″/G′) of a loss modulus (G″) to a storage modulus (G′). For example, the adhesive member AP may have the loss tangent of (e.g., at most) about 2.4 or less as measured by the dynamic viscoelasticity measurement in the shear (torsion) mode at the frequency of about 1 Hz and at the temperature of about −20° C.

The adhesive member AP, which has the loss tangent of less than (e.g., at most) about 2.0 as measured by the dynamic viscoelasticity measurement in the shear (torsion) mode at the frequency of about 1 Hz and at the temperature of about −20° C., may not be good or suitable in bending characteristic(s) and thus may not be suitable to be used for the flexible display device. In contrast, the adhesive member AP according to one or more embodiments, which has the loss tangent of (e.g., at least) about 2.0 MPa or more as measured by the dynamic viscoelasticity measurement in the shear (torsion) mode at the frequency of about 1 Hz and at the temperature of about −20° C., may exhibit excellent or suitable flexibility. In one or more embodiments, the display device DD including the adhesive member AP may exhibit excellent or suitable reliability. For example, an adhesive member with a loss tangent of less than (e.g., at most) about 2.0 at −20° C. is likely to have poor bending characteristics, making it unsuitable for use in a flexible display device. Conversely, an adhesive member with a loss tangent of about 2.0 or more at −20° C., as described in one or more embodiments, provides excellent flexibility. Consequently, a display device that includes this adhesive member may exhibit excellent reliability.

In one or more embodiments, the adhesive member AP may have a 180° peel strength of (e.g., at least) about 300 gram force per 25 millimeter (gf/25 mm) or more for at least one of a glass substrate or a polymer substrate at a temperature of about 25° C. The adhesive member AP may have the 180° peel strength of (e.g., at most) about 900 gf/25 mm or less for at least one of the glass substrate or the polymer substrate at the temperature of about 25° C. For example, the polymer substrate may include polyethylene terephthalate (PET). The adhesive member AP having the 180° peel strength of (e.g., at least) about 300 gf/25 mm or more for at least one of the glass substrate or the polymer substrate at the temperature of about 25° C. may exhibit excellent or suitable reliability of adhesion. The display device DD including the adhesive member AP, which has the 180° peel strength of (e.g., at least) about 300 gf/25 mm or more for at least one of the glass substrate or the polymer substrate at the temperature of about 25° C., may exhibit excellent or suitable reliability. In contrast, the adhesive member AP, which has the 180° peel strength of less than (e.g., at most) about 300 gf/25 mm for at least one of the glass substrate or the polymer substrate at the temperature of about 25° C., may have low adhesion, and thus may be separated from a component (e.g., display module and/or window) of the display device in a case of being included in the display device. For example, an adhesive member with a 180° peel strength of at least 300 gf/25 mm at 25° C. for either a glass or polymer substrate, such as PET, ensures excellent adhesion and reliability for display devices. Conversely, an adhesive member with a peel strength below 300 gf/25 mm at 25° C. may exhibit low adhesion, leading to potential separation from display components.

In one or more embodiments, the adhesive member AP may have a glass transition temperature (Tg) of about −46° C. to about −39° C. An adhesive member having a glass transition temperature of more than about −39° C. may be vulnerable to an external impact due to very high cohesion of a polymer constituting the adhesive member, and thus may not be suitable to be used for the display device. The adhesive member AP according to one or more embodiments having the glass transition temperature of about −46° C. to about −39° C. may be good or suitable in cohesion of a polymer constituting the adhesive member AP, and exhibit excellent or suitable impact resistance. The adhesive member AP according to one or more embodiments having the glass transition temperature of (e.g., at most) about −39° C. or less may exhibit a characteristic of being easy to repeatedly fold and unfold in a relatively-low-temperature environment. In one or more embodiments, the display device DD including the adhesive member AP according to one or more embodiments having the glass transition temperature of about −46° C. to about −39° C. may exhibit excellent or suitable reliability. For example, an adhesive member with a glass transition temperature (Tg) between −46° C. and −39° C. offers suitable cohesion and excellent impact resistance, making it ideal for display devices. Conversely, an adhesive member with a Tg above −39° C. may be too cohesive and vulnerable to external impacts, making it unsuitable for such applications. Additionally, an adhesive member with a Tg of −39° C. or lower may easily be folded and unfolded in low-temperature environments, enhancing the reliability of the display device.

In one or more embodiments, the adhesive member AP may be made from the resin composition RC (see FIGS. 5A and 6A) according to one or more embodiments. Accordingly, the adhesive member AP according to one or more embodiments may satisfy the foregoing storage modulus, 180° peel strength, and glass transition temperature.

FIG. 4 is a cross-sectional view specifically illustrating the display module DM in FIG. 3. Components of the display module DM illustrated in FIG. 4 are illustrative, and one or more embodiments is not limited thereto.

In FIG. 4, a base substrate BS may include a single layer or a plurality of layers. For example, the base substrate BS may include a first synthetic resin layer, an inorganic layer having a multilayer or single-layer structure, and a second synthetic resin layer arranged on the inorganic layer having the multilayer or single-layer structure. Each of the first synthetic resin layer and the second synthetic resin layer may include a polyimide-based resin. Each of the first synthetic resin layer and the second synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. The term “X-based” resin used herein refers to a resin including a functional group of “X”.

A display panel DP may include a transistor TR and a light emitting element ED. The transistor TR and the light emitting element ED may be arranged on the base substrate BS. FIG. 4 illustrates one transistor TR, but the display panel DP may substantially include a plurality of transistors and at least one capacitor for driving the light emitting element ED.

A circuit layer DP-CL may be arranged on the base substrate BS. The circuit layer DP-CL may include a shielding electrode BML, the transistor TR, a connection electrode CNE, and a plurality of insulation layers BFL and INS1 to INS6. The plurality of insulation layers BFL and INS1 to INS6 may include a buffer layer BFL and first to sixth insulation layers INS1 to INS6. However, a stack structure of the circuit layer DP-CL illustrated in FIG. 4 is illustrative, and the stack structure of the circuit layer DP-CL may be changed according to the configuration of the display panel DP and a process of the circuit layer DP-CL and/or the like.

The shielding electrode BML may be arranged on the base substrate BS. The shielding electrode BML may overlap the transistor TR. The shielding electrode BML may protect the transistor TR by blocking light which is incident on the transistor TR from below the display panel DP. The shielding electrode BML may include a conductive material. When a voltage is applied to the shielding electrode BML, a threshold voltage of the transistor TR arranged on the shielding electrode BML may be maintained. However, one or more embodiments is not limited thereto, and the shielding electrode BML may be a floating electrode. The shielding electrode BML may not be provided.

The buffer layer BFL may be arranged on the base substrate BS to cover the shielding electrode BML. The buffer layer BFL may include an inorganic layer. The buffer layer BFL may improve a bonding force between the base substrate BS and a semiconductor pattern or conductive pattern arranged on the buffer layer BFL.

The transistor TR may include a source S1, a channel C1, a drain D1, and a gate G1. The source S1, the channel C1, and the drain D1 of the transistor TR may be provided from the semiconductor pattern. The semiconductor pattern of the transistor TR may include polysilicon, amorphous silicon, and/or metal oxide, and the material thereof may be applied without being limited as long as having semiconductor properties, and is not limited to any one thereof.

The semiconductor pattern may include a plurality of regions divided according to a magnitude of conductivity. A region of the semiconductor pattern, which is doped with a dopant or in which a metal oxide is reduced, may have high conductivity, and may substantially serve as each of a source electrode and a drain electrode of the transistor TR. The region, which has high conductivity, of the semiconductor pattern may correspond to each of the source S1 and the drain D1 of the transistor TR. A region, which has low conductivity by being non-doped or doped at a low concentration or by a metal oxide being non-reduced, of the semiconductor pattern may correspond to the channel C1 (or active) of the transistor TR.

The first insulation layer INS1 may cover the semiconductor pattern of the transistor TR and be arranged on the buffer layer BFL. The gate G1 of the transistor TR may be arranged on the first insulation layer INS1. The gate G1 may overlap the channel C1 of the transistor TR on a plane. The gate G1 may function as a mask in a process of doping the semiconductor pattern of the transistor TR.

The second insulation layer INS2 may cover the gate G1 and be arranged on the first insulation layer INS1. The third insulation layer INS3 may be arranged on the second insulation layer INS2.

The connection electrode CNE may include a first connection electrode CNE1 and a second connection electrode CNE2 which are provided to electrically connect the transistor TR and the light emitting element ED to each other. However, the components of the connection electrode CNE, which electrically connect the transistor TR and the light emitting element ED to each other, are not limited thereto. For example, one of the first and second connection electrodes CNE1 and CNE2 may not be provided, or an additional connection electrode may be further included.

The first connection electrode CNE1 may be arranged on the third insulation layer INS3. The first connection electrode CNE1 may be connected to the drain D1 through a first contact hole CH1 passing through the first to third insulation layers INS1 to INS3. The fourth insulation layer INS4 may cover the first connection electrode CNE1 and be arranged on the third insulation layer INS3. The fifth insulation layer INS5 may be arranged on the fourth insulation layer INS4.

The second connection electrode CNE2 may be arranged on the fifth insulation layer INS5. The second connection electrode CNE2 may be connected to the first connection electrode CNE1 through a second contact hole CH2 passing through the fourth and fifth insulation layers INS4 and INS5. The sixth insulation layer INS6 may cover the second connection electrode CNE2 and be arranged on the fifth insulation layer INS5.

Each of the first to sixth insulation layers INS1 to INS6 may include an inorganic layer and/or an organic layer. For example, the inorganic layer may include at least one of an aluminum oxide, a titanium oxide, a silicon oxide, a silicon oxynitride, a zirconium oxide, or a hafnium oxide. The organic layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

A display element layer DP-EL may include a pixel defining film PDL and the light emitting element ED. The light emitting element ED may include a first electrode AE, a hole control layer HCL, a light emitting layer EML, an electron control layer TCL, and a second electrode CE.

The first electrode AE may be arranged on the sixth insulation layer INS6. The first electrode AE may be connected to the second connection electrode CNE2 through a third contact hole CH3 passing through the sixth insulation layer INS6. The first electrode AE may be electrically connected to the drain D1 of the transistor TR through the first and second connection electrodes CNE1 and CNE2.

The first electrode AE may be made of a metal material, a metal alloy, and/or a conductive compound. The first electrode AE may be an anode or a cathode. However, one or more embodiments is not limited thereto. The first electrode AE may be a pixel electrode. The first electrode AE may be a transmissive electrode, a semi-transmissive electrode, or a reflective electrode. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

In a case in which the first electrode AE is a transmissive electrode, the first electrode AE may include a transparent metal oxide, for example, an indium tin oxide (ITO), an indium zinc oxide (IZO), a zinc oxide (ZnO), an indium tin zinc oxide (ITZO) and/or the like. In a case in which the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (stacked structure of LiF and Ca), LiF/AI (stacked structure of LiF and AI), Mo, Ti, W, or a (e.g., any suitable) compound or mixture thereof (e.g., mixture of Ag and Mg). In one or more embodiments, the first electrode AE may have a multilayer structure including a reflective film or a semi-transmissive film, each of which is made of the foregoing material, and a transparent conductive film made of an indium tin oxide (ITO), an indium zinc oxide (IZO), a zinc oxide (ZnO), an indium tin zinc oxide (ITZO) and/or the like. For example, the first electrode AE may have a three-layer structure of ITO/Ag/ITO, but the present disclosure is not limited thereto. However, one or more embodiments is not limited thereto, and the first electrode AE may include the foregoing metal material, a combination of two or more metal materials selected from among the foregoing metal materials, an oxide of the foregoing metal materials, and/or the like.

The pixel defining film PDL may be arranged on the sixth insulation layer INS6. A light emitting opening portion PX_OP which exposes a portion of the first electrode AE may be defined in the pixel defining film PDL. The portion of the first electrode AE, which is exposed by the light emitting opening portion PX_OP, may be defined as a light emitting area LA.

A display area AA-DM of the display module DM may include the light emitting area LA and at least one light shielding area NLA. An area in which the pixel defining film PDL is arranged may correspond to the light shielding area NLA. The light shielding area NLA may be around (e.g., surround) the light emitting area LA within the display area AA-DM.

The hole control layer HCL may be arranged on the first electrode AE and the pixel defining film PDL. The hole control layer HCL may be provided as a common layer overlapping the light emitting area LA and the light shielding area NLA. In one or more embodiments, the hole control layer HCL may be provided only in an area corresponding to the light emitting opening portion PX_OP. The hole control layer HCL may include at least one of a hole transport layer, a hole injection layer, or an electron blocking layer. The hole control layer HCL may include a suitable hole injection material and/or a suitable hole transport material.

The light emitting layer EML may be arranged on the hole control layer HCL. The light emitting layer EML may be arranged in an area corresponding to the light emitting opening portion PX_OP. In one or more embodiments, the light emitting layer EML may be provided as a common layer. The light emitting layer EML may include an organic light emitting material and/or an inorganic light emitting material. The light emitting layer EML may be to emit light having any one color selected from among red, green, and blue colors. For example, the light emitting layer EML may be to emit light having a blue color.

The electron control layer TCL may be arranged on the light emitting layer EML. The electron control layer TCL may be provided as a common layer overlapping the light emitting area LA and the light shielding area NLA. In one or more embodiments, the electron control layer TCL may be provided only in an area corresponding to the light emitting opening portion PX_OP. The electron control layer TCL may include at least one of an electron transport layer, an electron injection layer, or a hole blocking layer. The electron control layer TCL may include a suitable electron injection material and/or a suitable electron transport material.

The second electrode CE may be arranged on the electron control layer TCL. The second electrode CE may be provided as a common layer overlapping the light emitting area LA and the light shielding area NLA.

The second electrode CE may be a common electrode. The second electrode CE may be a cathode or an anode, but one or more embodiments is not limited thereto. For example, in a case in which the first electrode AE is an anode, the second electrode CE may be a cathode, and in a case in which the first electrode AE is a cathode, the second electrode CE may be an anode.

The second electrode CE may be a transmissive electrode, a semi-transmissive electrode, or a reflective electrode. In a case in which the second electrode CE is a transmissive electrode, the second electrode CE may be made of a transparent metal oxide, for example, an indium tin oxide (ITO), an indium zinc oxide (IZO), a zinc oxide (ZnO), an indium tin zinc oxide (ITZO), and/or the like.

In a case in which the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, or a (e.g., any suitable) compound or mixture thereof (e.g., AgMg, AgYb or MgYb). In one or more embodiments, the second electrode CE may have a multilayer structure including a reflective film or a semi-transmissive film, each of which is made of the foregoing material, and a transparent conductive film made of an indium tin oxide (ITO), an indium zinc oxide (IZO), a zinc oxide (ZnO), an indium tin zinc oxide (ITZO) and/or the like. For example, the second electrode CE may include the foregoing metal material, a combination of two or more metal materials selected from among the foregoing metal materials, an oxide of the foregoing metal materials, and/or the like.

An encapsulating layer TFE may be arranged on the second electrode CE to cover the light emitting element ED. The encapsulating layer TFE may include a plurality of thin films. For example, the encapsulating layer TFE may include inorganic films arranged on the second electrode CE, and an organic film arranged between the inorganic films. The inorganic films may protect the light emitting element ED from moisture and/or oxygen, and the organic film may protect the light emitting element ED from foreign matter such as dust particles.

An input sensing part TP may include a first sensing insulation layer IL1, a second sensing insulation layer IL2, and a third sensing insulation layer IL3. The input sensing part TP may include at least one conductive layer arranged on the sensing insulation layers. The input sensing part TP may include a first conductive layer CDL1 and a second conductive layer CDL2.

The first sensing insulation layer IL1 may be arranged on the encapsulating layer TFE. The first sensing insulation layer IL1 may include at least one inorganic insulation layer. The first sensing insulation layer IL1 may be in contact with the encapsulating layer TFE. In one or more embodiments, the first sensing insulation layer IL1 may not be provided, and in this case, the first conductive layer CDL1 may be in contact with the encapsulating layer TFE.

The first conductive layer CDL1 may be arranged on the first sensing insulation layer IL1. The first conductive layer CDL1 may include a plurality of first conductive patterns. The plurality of first conductive patterns may be arranged on the first sensing insulation layer IL1. The second sensing insulation layer IL2 may be arranged on the first sensing insulation layer IL1 so as to cover at least a portion of the first conductive layer CDL1.

The second conductive layer CDL2 may be arranged on the second sensing insulation layer IL2. The second conductive layer CDL2 may include a plurality of second conductive patterns. The plurality of second conductive patterns may be arranged on the second sensing insulation layer IL2. The plurality of second conductive patterns may be connected to the plurality of first conductive patterns through contact holes defined in the second sensing insulation layer IL2, respectively.

Each of the plurality of first conductive patterns of the first conductive layer CDL1 and the plurality of second conductive patterns of the second conductive layer CDL2 may be arranged to correspond to the light shielding area NLA. Each of the plurality of first conductive patterns of the first conductive layer CDL1 and the plurality of second conductive patterns of the second conductive layer CDL2 may correspond to a mesh pattern.

The third sensing insulation layer IL3 may be arranged on the second sensing insulation layer IL2, and may cover the second conductive layer CDL2. Each of the second sensing insulation layer IL2 and the third sensing insulation layer IL3 may include an inorganic insulation layer or an organic insulation layer.

Each of the first conductive layer CDL1 and the second conductive layer CDL2 may have a single-layer structure, or have a multilayer structure in which layers are stacked in the third direction DR3. The conductive layers CDL1 and CDL2 each having a single-layer structure may include a metal layer or a transparent conductive layer. The metal layer may include molybdenum, silver, titanium, copper, aluminum, or an (e.g., any suitable) alloy thereof. The transparent conductive layer may include a transparent conductive oxide such as an indium tin oxide (ITO), an indium zinc oxide (IZO), a zinc oxide (ZnO), and/or an indium zinc tin oxide (IZTO). The transparent conductive layer may include a conductive polymer such as PEDOT, a metal nanowire, graphene, and/or the like.

The conductive layers CDL1 and CDL2 each having a multilayer structure may include metal layers. The metal layers may have, for example, a three-layer structure of titanium (Ti)/aluminum (Al)/titanium (Ti). Each of the conductive layers CDL1 and CDL2 having a multilayer structure may include at least one metal layer and at least one transparent conductive layer.

FIGS. 5A to 5D are schematic views illustrating a method for manufacturing the adhesive member AP (see FIG. 3) from a resin composition RC according to one or more embodiments. For example, the method for manufacturing the adhesive member AP (see FIG. 3) may include providing the resin composition RC on a substrate CF, providing first light UV-1 to the resin composition RC to form a preliminary adhesive member P-AP, and providing second light UV-2 to the preliminary adhesive member P-AP to form the adhesive member AP (see FIG. 3). Hereinafter, one or more embodiments will be described with reference to FIGS. 5A to 5D by avoiding the contents in common with the contents described with reference to FIGS. 1 to 4, and mainly in terms of differences in more detail.

Referring to FIG. 5A, the resin composition RC according to one or more embodiments may be provided on the substrate CF. The resin composition RC may be provided on the substrate CF through a nozzle NZ. For example, the substrate CF on which the resin composition RC is provided may include polyethylene terephthalate (PET). The substrate CF is a temporary substrate used to form the adhesive member AP (see FIG. 3) from the resin composition RC, and a substrate may be used without being limited as long as the resin composition RC is easily detachable therefrom after being cured (e.g., once cured). One or more surface(s) of the substrate CF on which the resin composition RC is provided may have been release-treated.

The resin composition RC according to one or more embodiments may be provided by an inkjet printing method or a dispensing method. When the resin composition RC is provided by the inkjet printing method or the dispensing method, the resin composition RC may exhibit a characteristic of being easy to apply onto members having one or more suitable shapes included in the display device DD (see FIG. 1A).

In one or more embodiments, the resin composition RC in a liquid state may be provided in a substantially uniform amount and/or at a substantially uniform rate. FIG. 5A illustrates the resin composition RC being provided through the nozzle NZ, but a machine for providing the resin composition RC is not limited thereto.

The resin composition RC according to one or more embodiments may have a shear viscosity of about 5 millipascal second (mPa·s) to about 50 mPa·s as measured at a temperature of about 25° C. according to JIS Z8803. The resin composition RC having the shear viscosity of about 5 mPa·s to about 50 mPa·s as measured at the temperature of about 25° C. according to JIS Z8803 may exhibit a low-viscosity characteristic and thus be provided by an inkjet printing method or a dispensing method. In the resin composition RC having the shear viscosity of less than (e.g., at most) about 5 mPa·s as measured at the temperature of about 25° C. according to JIS Z8803, flowing occurs if (e.g., when) the resin composition is provided. As used herein, the term “flowing” refers to a phenomenon in which the resin composition flows out of a member to which the resin composition is intended to be provided. The resin composition RC having the shear viscosity of more than about 50 mPa·s as measured at the temperature of about 25° C. according to JIS Z8803 is not easily ejected from a machine such as the nozzle NZ, and is not applied in a substantially uniform amount and/or in a substantially uniform thickness. For example, a resin composition with a shear viscosity between 5 mPa·s and 50 mPa·s at 25° C., as measured according to JIS Z8803, exhibits low viscosity, making it suitable for application via inkjet printing or dispensing methods. If the viscosity is below 5 mPa·s, the resin may flow uncontrollably from the intended application area. Conversely, if the viscosity exceeds 50 mPa·s, the resin is difficult to eject uniformly from a nozzle, leading to inconsistent application. The measurement method follows the standards set by JIS Z8803, which is incorporated herein by reference in its entirety.

The resin composition RC according to one or more embodiments may include at least one monofunctional (meth)acrylate monomer, an organopolysiloxane, and at least one photoinitiator including a radical polymerization initiator. The resin composition RC according to one or more embodiments may further include a urethane (meth)acrylate oligomer and/or a silane coupling agent. In the present disclosure, a (meth)acryloyl group refers to an acryloyl group or a methacryloyl group, and (meth)acryl refers to acryl or methacryl.

The resin composition RC according to one or more embodiments may include at least one photoinitiator. The photoinitiator may include a radical polymerization initiator. For example, the resin composition RC may include Omnirad 819 (produced by IGM Resin) as the photoinitiator.

In a case in which the resin composition RC includes a plurality of photoinitiators, different photoinitiators may be activated by ultraviolet light having different center wavelengths. For example, the photoinitiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In one or more embodiments, the photoinitiator may include at least one of 2-methyl-1 [4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, Ethyl(2,4,6-trimethylbenzoyl)phenyl phosphinate, Phenylbis(2,4,6-trimethylbenzoyl) phosphine oxide), [1-(4-phenylsulfanylbenzoyl) heptylideneamino]benzoate, [1-[9-ethyl-6-(2-methylbenzoyl) carbazol-3-yl]ethylideneamino]acetate, or Bis(2,4-cyclopentadienyl)bis [2,6-difluoro-3-(1-pyrryl)phenyl]titanium (IV).

The resin composition RC may include at least one monofunctional (meth)acrylate monomer. For example, based on a total of 100 wt % (weight percent) of the resin composition, an amount of the monofunctional (meth)acrylate monomer may be about 60 wt % to about 85 wt %. The resin composition RC which satisfies the foregoing amount of the monofunctional (meth)acrylate monomer may exhibit a low shear viscosity before curing, and exhibit excellent or suitable flexibility and excellent or suitable adhesion after the curing (e.g., once cured).

In the resin composition RC, the monofunctional (meth)acrylate monomer may include at least one of alicyclic (meth)acrylate, hydroxyl group-containing (meth)acrylate, alkyl (meth)acrylate, or aromatic (meth)acrylate. For example, the monofunctional (meth)acrylate monomer may include at least one of 4-hydroxybutyl acrylate (4-HBA), 2-ethylhexyl acrylate (2-EHA), tetrahydrofurfuryl acrylate (THF-A), or 2-ethylhexyl-diglycol acrylate (EHDG-AT).

The resin composition RC according to one or more embodiments may include an organopolysiloxane. In the resin composition RC according to one or more embodiments, the organopolysiloxane may have a weight average molecular weight (Mw) of about 500 to about 50,000. For example, the weight average molecular weight of the organopolysiloxane may be about 1,000 to about 5,000. In the resin composition RC according to one or more embodiments, the organopolysiloxane may include at least one of KR510 (produced by Shin-Etsu Chemical Co., Ltd.) or X-48-1501 (produced by Shin-Etsu Chemical Co., Ltd.). The resin composition RC according to one or more embodiments including the organopolysiloxane having the weight average molecular weight of about 500 or more and less than (e.g., at most) about 50,000 may satisfy the foregoing shear viscosity (i.e., about 5 mPa·s to about 50 mPa·s). In some embodiments, the resin composition RC according to one or more embodiments including the organopolysiloxane having the weight average molecular weight of (e.g., at least) about 500 or more and less than (e.g., at most) about 50,000 may exhibit excellent or suitable optical transparency, excellent or suitable flexibility, and excellent or suitable adhesion after curing (e.g., once cured).

In one or more embodiments, an amount of the organopolysiloxane may be (e.g., at least) about 5 wt % or more and less than (e.g., at most) about 35 wt % based on the total of 100 wt % of the resin composition RC. The resin composition including about 35 wt % or more of the organopolysiloxane based on the total of 100 wt % of the resin composition may be decreased in optical transparency and exhibit low adhesion after the curing (e.g., once cured). When the optical transparency is decreased, the resin composition may not transmit an image generated in the display module DM (see FIG. 2) to exhibit low display quality. The resin composition, which includes less than (e.g., at most) about 5 wt % of the organopolysiloxane based on the total of 100 wt % of the resin composition, may have a high storage modulus after the curing (e.g., once cured), and may not be suitable for the flexible display device due to insufficient flexibility.

In contrast, in one or more embodiments, the resin composition RC including (e.g., at least) about 5 wt % or more and less than (e.g., at most) about 35 wt % of the organopolysiloxane based on the total of 100 wt % of the resin composition RC may have the storage modulus of (e.g., at most) about 1 MPa or less as measured by the dynamic viscoelasticity measurement in the shear mode at the frequency of about 1 Hz and at the temperature of about −20° C. after the curing (e.g., once cured), and have the 180° peel strength of (e.g., at least) about 300 gf/25 mm or more for at least one of the polymer substrate or the glass substrate at the temperature of about 25° C. after the curing (e.g., once cured). Thus, the resin composition RC including (e.g., at least) about 5 wt % or more and less than (e.g., at most) about 35 wt % of the organopolysiloxane based on the total of 100 wt % of the resin composition RC may exhibit excellent or suitable flexibility and excellent or suitable adhesion after the curing (e.g., once cured), and exhibit a characteristic suitable for the flexible display device (see FIG. 1A).

In one or more embodiments, the organopolysiloxane does not include a (e.g., excludes any) radical polymerizable group. The radical polymerizable group refers to a group capable of being polymerized by action of (e.g., reacting with) a radical. For example, the radical polymerizable group may include, as a group including an unsaturated bond, an alkenyl group, a vinyl group, a (meth)acryloyl group, an allyl group, an isopropenyl group, a styryl group, a vinyloxy group, a vinyloxycarbonyl group, a vinylcarbonyl group, an N-vinylamino group, and/or the like.

In one or more embodiments, the organopolysiloxane may include no radical polymerizable group but may include a moisture-curable siloxane. Accordingly, even a portion, which is insufficient in amount of light provided to form the adhesive member AP (see FIG. 3) from the resin composition RC, may exhibit excellent or suitable curability. The preliminary adhesive member P-AP (see FIG. 5C) may be formed from the resin composition RC. Thereafter, the second light UV-2 provided to form the adhesive member AP (see FIG. 3) from the preliminary adhesive member P-AP (see FIG. 5C) may not easily pass through a print layer BM (see FIG. 5C). A portion (i.e., portion overlapping the print layer BM) of the preliminary adhesive member P-AP (see FIG. 5C) may not be sufficiently irradiated with the second light UV-2 due to the print layer BM (see FIG. 5C). However, in one or more embodiments, in the adhesive member AP (see FIG. 3) formed from the resin composition RC including the organopolysiloxane including no radical polymerizable group, even a portion overlapping the print layer BM (see FIG. 5C) may exhibit excellent or suitable curability.

In one or more embodiments, the resin composition RC may further include a urethane (meth)acrylate oligomer. For example, in the resin composition RC, the urethane (meth)acrylate oligomer may have a weight average molecular weight of about 10,000 to about 40,000. In the resin composition RC, the urethane (meth)acrylate oligomer may include at least one of UF-C051 (urethane acrylate, product by Kyoeisha Chemical Co., Ltd.), UF-C052 (urethane acrylate, product by Kyoeisha Chemical Co., Ltd.), or UN6304 (urethane acrylate, product by Negami Chemical Industrial Co., Ltd.). However, this is illustrative, and the urethane (meth)acrylate oligomer included in the resin composition RC is not limited thereto.

In one or more embodiments, the resin composition RC may further include a silane coupling agent. For example, the resin composition RC may include KBM403 (produced by Shin-Etsu Chemical Co., Ltd.) as the silane coupling agent. However, this is illustrative, and the silane coupling agent included in the resin composition RC is not limited thereto.

In one or more embodiments, the resin composition RC may not include a (e.g., may exclude any) solvent. The solvent refers to a liquid for dissolving a material (e.g., monomer, oligomer and/or the like) constituting a composition. A resin composition including the solvent requires drying time and/or the like after applying the resin composition. In contrast, the resin composition RC according to one or more embodiments that does not include the solvent may require no drying time and/or the like after applying the resin composition RC, and be provided by an inkjet printing method or a dispensing method, thereby exhibiting excellent or suitable manufacturing efficiency.

Referring to FIG. 5B, the first light UV-1 may be provided to the resin composition RC applied in a constant thickness on the substrate CF. The liquid resin composition RC may be cured by the first light UV-1 to form the preliminary adhesive member P-AP (see FIG. 5C). The first light UV-1 may be ultraviolet light. FIG. 5B illustrates the preliminary adhesive member P-AP being formed by emitting the first light UV-1 directly onto the resin composition RC applied on the substrate CF, but one or more embodiments is not limited thereto. In one or more embodiments, a carrier film may be arranged on the resin composition RC applied in a substantially uniform thickness onto the substrate CF, and the carrier film may be to transmit ultraviolet light.

Referring to FIGS. 5C and 5D, the preliminary adhesive member P-AP formed by emitting the first light UV-1 (see FIG. 5B) onto the resin composition RC may be detached from the substrate CF to be provided on one surface of a window WP or one surface of a display module DM. One surface of the preliminary adhesive member P-AP may be laminated on the one surface of the window WP or the one surface of the display module DM, and the one surface of the window WP or the one surface of the display module DM, which is not attached, may be attached to the other surface of the preliminary adhesive member P-AP. Thereafter, the second light UV-2 may be emitted onto the preliminary adhesive member P-AP to form the adhesive member AP (see FIG. 3). The second light UV-2 may be ultraviolet light. The second light UV-2 may be provided from above the window WP, and the window WP may be to transmit the second light UV-2. The second light UV-2 may pass through the window WP to be provided to the preliminary adhesive member P-AP.

FIGS. 5A to 5D illustrate curing the resin composition RC two times (i.e., performing the curing by providing light two times) to form the adhesive member AP (see FIG. 3), but one or more embodiments is not limited thereto. For example, the resin composition RC (see FIG. 5A) may be cured once (i.e., providing light one time) to form the adhesive member AP (see FIG. 3), or alternatively may be cured three times (i.e., providing light three times) or more to form the adhesive member AP (see FIG. 3).

The resin composition RC (see FIG. 5A) according to one or more embodiments may be cured by the light UV-1 and UV-2. For example, the resin composition RC (see FIG. 5A) may be cured by the ultraviolet light to form the adhesive member AP (see FIG. 3). The resin composition RC (see FIG. 5A) according to one or more embodiments may be optically transparent after being cured by the light (e.g., once cured). Being optically transparent after curing may refer to having excellent or suitable miscibility after curing. Being optically transparent may refer to that a transmittance of light in a visible light wavelength range is 80% or more.

The resin composition RC (see FIG. 5A) according to one or more embodiments may have a storage modulus of (e.g., at most) about 1 MPa or less as measured by dynamic viscoelasticity measurement in a shear mode at a frequency of about 1 Hz and at a temperature of about −20° C. after being cured by the light (e.g., once cured). The resin composition RC (see FIG. 5A) according to one or more embodiments may have a 180° peel strength of (e.g., at least) about 300 gf/25 mm or more for at least one of a polymer substrate or a glass substrate at a temperature of about 25° C. after being cured by the light (e.g., once cured). The resin composition RC (see FIG. 5A) according to one or more embodiments may have a glass transition temperature of about −46° C. to about −39° C. after being cured by the light (e.g., once cured). The resin composition RC according to one or more embodiments may include a monofunctional (meth)acrylate monomer, an organopolysiloxane, and a radical polymerization initiator, thereby satisfying the foregoing shear viscosity before the curing and satisfying the foregoing storage modulus, 180° peel strength, and glass transition temperature after the curing (e.g., once cured).

FIGS. 6A to 6C are schematic views illustrating another method for manufacturing the adhesive member AP (see FIG. 3) from a resin composition RC according to one or more embodiments. Hereinafter, one or more embodiments will be described with reference to FIGS. 6A to 6C by avoiding the contents in common with the contents described with reference to FIGS. 1 to 5D, and mainly in terms of differences in more detail.

The method for manufacturing the adhesive member AP illustrated in FIGS. 6A to 6C may include providing the resin composition RC on a display module DM, providing first light UV-1 to the resin composition RC to form a preliminary adhesive member P-AP, and providing second light UV-2 to the preliminary adhesive member P-AP to form the adhesive member AP (see FIG. 3). Compared to the manufacturing method illustrated in FIGS. 5A to 5D, the manufacturing method illustrated in FIGS. 6A to 6C is different in that the resin composition RC is provided on the display module DM.

The resin composition RC may be provided directly on one surface of the display module DM or one surface of a window WP. FIG. 6A illustrates the resin composition RC being provided directly on the one surface of the display module DM.

The resin composition RC having a shear viscosity of about 5 mPa·s to about 50 mPa·s as measured at a temperature of about 25° C. according to JIS Z8803 may be provided while covering a bend of a stepped portion SP-b of the display module DM. As the resin composition RC has the low shear viscosity of (e.g., at most) about 50 mPa·s or less, the resin composition RC may be applied so that an empty space does not occur at a portion with a bend like the stepped portion SP-b. In some embodiments, the resin composition RC having the shear viscosity of (e.g., at least) about 5.0 mPa·s or more may be uniformly (e.g., substantially uniformly) applied in a set or predetermined thickness without flowing out of a portion, i.e., the display module DM, to which the resin composition RC is intended to be provided.

Referring to FIG. 6B, the first light UV-1 may be provided to the uniformly (e.g., substantially uniformly) applied resin composition RC. As the first light UV-1 is provided to the resin composition RC, the preliminary adhesive member P-AP (see FIG. 6C) may be formed. Referring to FIG. 6C, the window WP may be provided on the preliminary adhesive member P-AP. The second light UV-2 may pass through the window WP to be provided to the preliminary adhesive member P-AP. The preliminary adhesive member P-AP may be cured by the second light UV-2 to form the adhesive member AP (see FIG. 3).

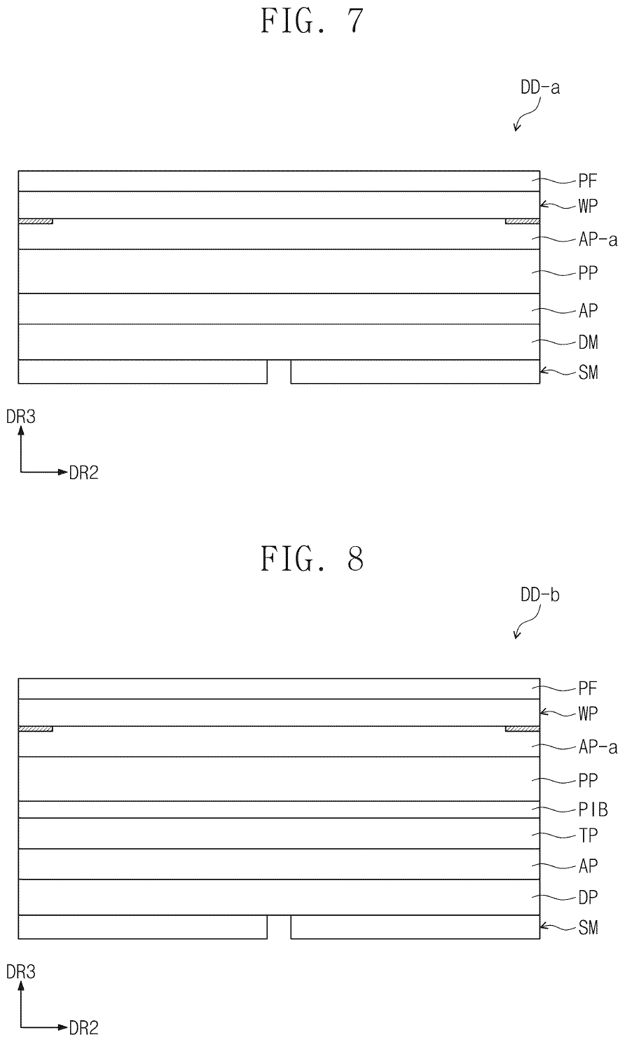

FIG. 7 may be a cross-sectional view illustrating a display device DD-a according to one or more embodiments of the disclosure. Hereinafter, the display device illustrated in FIG. 7 will be described by avoiding the contents in common with the contents described with reference to FIGS. 1 to 6C, and mainly in terms of differences in more detail.

Compared to the display device DD described with reference to FIGS. 2 and 3, the display device DD-a illustrated in FIG. 7 may further include a light control layer PP and an optical adhesive layer AP-a. The display device DD-a according to one or more embodiments may further include the light control layer PP arranged between an adhesive member AP and a window WP, and the optical adhesive layer AP-a arranged between the light control layer PP and the window WP. The light control layer PP may include a polarizer or a color filter layer.

The optical adhesive layer AP-a may be made from the resin composition RC (see FIGS. 5A and 6A) according to one or more embodiments. The optical adhesive layer AP-a including a polymer derived from the resin composition RC (see FIGS. 5A and 6A) according to one or more embodiments may have a storage modulus of (e.g., at most) about 1 MPa or less as measured by dynamic viscoelasticity measurement in a shear mode at a frequency of about 1 Hz and at a temperature of about −20° C. The optical adhesive layer AP-a including the polymer derived from the resin composition RC (see FIGS. 5A and 6A) according to one or more embodiments may be optically transparent. The optical adhesive layer AP-a including the polymer derived from the resin composition RC (see FIGS. 5A and 6A) according to one or more embodiments may have a 180° peel strength of (e.g., at least) about 300 gf/25 mm or more for at least one of a glass substrate or a polymer substrate at a temperature of about 25° C. The optical adhesive layer AP-a including the polymer derived from the resin composition RC (see FIGS. 5A and 6A) according to one or more embodiments may exhibit excellent or suitable flexibility and excellent or suitable reliability of adhesion.

FIG. 8 is a cross-sectional view illustrating a display device DD-b according to one or more embodiments of the disclosure. Hereinafter, the display device DD-b according to one or more embodiments illustrated in FIG. 8 will be described by avoiding the contents in common with the contents described with reference to FIGS. 1 to 7, and mainly in terms of differences in more detail.

Compared to the display device DD described with reference to FIGS. 2 and 3, the display device DD-b illustrated in FIG. 8 may further include a light control layer PP, an optical adhesive layer AP-a, and an adhesive interlayer PIB. Like the display device DD-a according to one or more embodiments illustrated in FIG. 7, the display device DD-b according to one or more embodiments illustrated in FIG. 8 may further include the light control layer PP arranged between an adhesive member AP and a window WP, and the optical adhesive layer AP-a arranged between the light control layer PP and the window WP.

In the display device DD-b according to one or more embodiments, the adhesive member AP may be provided between a display panel DP and an input sensing part TP. For example, the input sensing part TP may not be arranged directly on the display panel DP, and the display panel DP and the input sensing part TP may be coupled to each other through the adhesive member AP. For example, the adhesive member AP may be arranged between the encapsulating layer TFE (see FIG. 3) of the display panel DP and the input sensing part TP.

The adhesive interlayer PIB may be provided below the light control layer PP. The adhesive interlayer PIB may be arranged between the input sensing part TP and the light control layer PP, and be made of an adhesive material having excellent or suitable resistance to moisture permeation. For example, the adhesive interlayer PIB may include polyisobutylene. The adhesive interlayer PIB may be arranged on the input sensing part TP to prevent or reduce corrosion of sensing electrodes of the input sensing part TP. The display device DD-b according to one or more embodiments may include the optical adhesive layer AP-a and the adhesive member AP, each of which is made from the resin composition RC (see FIGS. 5A and 6A) according to one or more embodiments, and the display device DD-b including the optical adhesive layer AP-a and the adhesive member AP may exhibit excellent or suitable reliability.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, a devices for manufacturing the display device, and/or other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device may be formed on one integrated circuit (IC) chip or on separate IC chips. Further, the one or more suitable components of the display device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

Hereinafter, a resin composition according to one or more embodiments of the present disclosure, and an adhesive member made from the resin composition will be specifically described referring to Examples and Comparative Examples. Examples described in more detail are each one example for enhancing understanding, and the scope of the present disclosure is not limited thereto.

### Examples

### 1. Preparation and Evaluation of Resin Compositions

Resin compositions according to Examples 1-2 to 1-5 and 2-2 to 2-5 and Comparative Examples 1-1, 1-6, 1-7, 2-1, 2-6, and 2-7 were prepared by using materials set forth in Table 1. The materials set forth in Table 1 were weighted using a light-shielding glass vial in respective amounts (g, gram), and were stirred using a roll mill at room temperature for about 12 hours.

### Shear Viscosity Measurement for Resin Compositions

In Table 1, the shear viscosity of each of the resin compositions was measured at a temperature of about 25° C. according to JIS Z8803. The shear viscosities of the resin compositions were measured using viscometer TVE-25L (product by TOKI SANGYO Co. Ltd.) under a rate condition of about 10 rpm.

### Molecular Weight Measurement for Organopolysiloxanes

Molecular weights of organopolysiloxanes were measured using a gel permeation chromatography (GPC) analyzer HLC-8420GPC that is a produced by TOSOH Corporation. TSKgel SUPER HZM-N was used as a measurement column, and tetrahydrofuran (THF) was used as a solvent to obtain weight average molecular weight values as standard polystyrene (PS)-equivalent values from a size exclusion chromatography (SEC) curve detected by a refractive index (RI) detector. The obtained molecular weights are set forth in data of the materials in Table 1.

TABLE 1

| | | Example Label | | | | | | |
|---|---|---|---|---|---|---|---|---|
| | | Comparative | | | | | Comparative | Comparative |
| | | 1-1 | 1-2 | 1-3 | 1-4 | 1-5 | 1-6 | 1-7 |
| (Meth)acrylate | 4-HBA | 7 | 7 | 7 | 7 | 7 | 7 | 7 |
| monomer | 2-EHA | 55 | 55 | 55 | 55 | 55 | 55 | 55 |
| | THF-A | 15 | 15 | 15 | 15 | 15 | 15 | 15 |
| | EHDG-AT | 12 | 12 | 12 | 12 | 12 | 12 | 12 |
| Urethane | UF-C051 | 3 | 3 | 3 | 3 | 3 | 3 | 3 |
| (meth)acrylate | UF-C052 | 3 | 3 | 3 | 3 | 3 | 3 | 3 |
| oligomer | UN6304 | 7 | 7 | 7 | 7 | 7 | 7 | 7 |
| Photoinitiator | Omnirad 819 | 3 | 3 | 3 | 3 | 3 | 3 | 3 |
| Organo- | KR510 | 5 | 20 | 40 | | 40 | 60 | |
| polysiloxane | X-48-1501 | | | | 20 | | | |
| Silicone | D-26 | | | | | 2 | | |
| curing | | | | | | | | |
| catalyst | | | | | | | | |
| Silane | KBM403 | 0.1 | 0.1 | 0.1 | 0.1 | 0.1 | 0.1 | 0.1 |
| coupling | | | | | | | | |
| agent | | | | | | | | |

| | | | | | | | |
|---|---|---|---|---|---|---|---|
| Shear viscosity | 15 | 16 | 18 | 17 | 18 | 14 | 15 |
| [25° C., mPa · s] | | | | | | | |

### Data of Materials in Table 1

4-HBA: 4-hydroxybutyl acrylate (product by Osaka Organic Chemical Industry Ltd.)
2-EHA: 2-ethylhexyl acrylate (product by Toagosei Co., Ltd.)
THF-A: Tetrahydrofurfuryl acrylate (product by Kyoeisha Chemical Co., Ltd.)
EHDG-AT: 2-ethylhexyl-diglycol acrylate (product by Kyoeisha Chemical Co., Ltd.)
UF-C051: Urethane acrylate (weight average molecular weight: 35,000, product by Kyoeisha Chemical Co., Ltd.)
UF-C052: Urethane acrylate (weight average molecular weight: 10,000, product by Kyoeisha Chemical Co., Ltd.)
UN6304: Urethane acrylate (weight average molecular weight: 10,000, product by Negami Chemical Industrial Co., Ltd.)
Omnirad 819: Phenylbis(2,4,6-trimethylbenzoyl) phosphine oxide (product by IGM Resins)
KR510: Organopolysiloxane (product by Shin-Etsu Chemical Co., Ltd., weight average molecular weight: 2,100)
X-48-1501: Organopolysiloxane (product by Shin-Etsu Chemical Co., Ltd., weight average molecular weight: 3,100)
D-26: Titanium-containing catalyst (product by Shin-Etsu Chemical Co., Ltd.)
KBM403: Silane coupling agent (product by Shin-Etsu Chemical Co., Ltd.)

In Table 1, D-26 is a catalyst provided to promote curing of organopolysiloxanes, and contains titanium.

Referring to Table 1, it may be seen that the resin compositions according to Examples 1-2 to 1-5 each have a shear viscosity of about 5 mPa·s to about 50 mPa·s as measured at a temperature of about 25° C. according to JIS Z8803. Thus, it may be ascertained that the resin compositions according to Examples 1-2 to 1-5 may be provided by an inkjet printing method or a dispensing method.

The resin compositions according to Examples 1-2 to 1-5 are each the resin composition according to one or more embodiments. The resin compositions according to Examples 1-2 to 1-5 each include a monofunctional (meth)acrylate monomer, an organopolysiloxane, and a radical polymerization initiator. Accordingly, it may be ascertained that the resin composition including a monofunctional (meth)acrylate monomer, an organopolysiloxane, and a radical polymerization initiator has the shear viscosity of about 5 mPa·s to about 50 mPa·s as measured at the temperature of about 25° C. according to JIS Z8803.

It may be seen that, in the resin compositions according to Examples 1-2 to 1-5, the weight average molecular weight of the organopolysiloxane is about 2,100 or about 3,100 and satisfies the foregoing weight average molecular weight range (about 500 to about 50,000) of the organopolysiloxane. In the resin compositions according to Examples 1-2 to 1-5, each of KR510 and X-48-1501 that are organopolysiloxanes does not include a (e.g., excludes any) radical polymerizable group.

Each of the resin compositions according to Examples 1-2 to 1-5 includes about 5 wt % or more and less than (e.g., at most) about 35 wt % of the organopolysiloxane based on a total of 100 wt % of the resin composition. For example, the resin composition according to Example 1-2 includes about 20 g of the organopolysiloxane with respect to a total weight of about 125.1 g, and when 125.1 g is converted to 100 wt %, 20 g is equivalent to about 16 wt %.

Each of the resin compositions according to Examples 1-2 to 1-5 includes about 60 wt % to about 85 wt % of the monofunctional (meth)acrylate monomer based on the total of 100 wt % of the resin composition. For example, the resin composition according to Example 1-2 includes about 89 g of the monofunctional (meth)acrylate monomer with respect to the total weight of about 125.1 g, and when 125.1 g is converted to 100 wt %, 89 g is equivalent to about 71 wt %.

In other words, the resin compositions in Examples 1-2 to 1-5 have a shear viscosity between 5 mPa·s and 50 mPa·s at 25° C., as per JIS Z8803, making them suitable for inkjet printing or dispensing methods. These compositions include a monofunctional (meth)acrylate monomer, an organopolysiloxane, and a radical polymerization initiator. The organopolysiloxane has a weight average molecular weight of about 2,100 or about 3,100, fitting within the specified range, and does not include any radical polymerizable group. Each composition contains 5-35 wt % organopolysiloxane and 60-85 wt % monofunctional (meth)acrylate monomer, ensuring excellent performance and reliability.

The resin compositions according to Comparative Examples 1-1 and 1-6 each include an organopolysiloxane. The resin composition according to Comparative Example 1-1 includes about 4.5 wt % of the organopolysiloxane based on the total of 100 wt % of the resin composition. The resin composition according to Comparative Example 1-6 includes about 36.3 wt % of the organopolysiloxane based on the total of 100 wt % of the resin composition. For example, the resin compositions according to Comparative Examples 1-1 and 1-6 do not satisfy the weight range (about 5 wt % or more and less than (e.g., at most) about 35 wt %) of the organopolysiloxane according to one or more embodiments. The resin composition according to Comparative Example 1-7 does not include an organopolysiloxane.

### 2. Evaluation of Adhesive Members

Table 2 shows results of evaluating miscibilities, storage moduli, glass transition temperatures, and 180° peel strengths of adhesive members made from the resin compositions according to Examples 1-2 to 1-5 and Comparative Examples 1-1, 1-6, and 1-7. The adhesive members according to Examples 2-2 to 2-5 were made from the resin compositions according to Examples 1-2 to 1-5, respectively. The adhesive members according to Comparative Examples 2-1, 2-6, and 2-7 were made from the resin compositions according to Comparative Examples 1-1, 1-6, and 1-7, respectively. Hereinafter, the evaluation method will be described in more detail.

### Measurement of Storage Moduli, Loss Tangents and Glass Transition Temperatures of Adhesive Members

A silicone rubber sheet, which had a circular empty hole having an inner diameter of about 8 millimeter (mm) and has a thickness of about 500 micrometer (μm), was placed on a release-treated PET film, and then 28 microliter (μL) of each of the resin compositions according to Examples 1-2 to 1-5 and Comparative Examples 1-1, 1-6, and 1-7 was provided in the empty hole. Thereafter, light was emitted using LED lamps having peaks at wavelengths of about 365 nanometer (nm) and about 395 nm so that total amounts of the light reach about 800 millijoule per square centimeter (mJ/cm²) and about 400 mJ/cm², respectively. Then, a PET film, which is substantially the same as the preceding described PET film, was provided, and a glass substrate having a thickness of about 1 mm was provided on the PET film. The light was emitted from above the glass substrate by using the LED lamp having the peak at the wavelength of about 395 nm so that the total amount of the light reached about 4,000 mJ/cm². Consequently, circle-shaped samples each having a diameter of about 8 mm and a thickness of about 500 μm were obtained.

The obtained samples were provided for dynamic viscoelasticity measurement. The measurement was performed using an MCR302 instrument (produced by Anton-Paar) at a frequency of about 1 Hz, in a shear mode, at a temperature of about −50° C. to about 80° C., and at a temperature increase rate of about 2 degrees Celsius per minute (° C./min). The storage moduli at the temperature of about −20° C., the loss tangents (tan δ) at the temperature of about −20° C., and the glass transition temperatures, each of which was checked through the measurement, were recorded in Table 2. Temperatures when values of the loss tangents (tan δ) were at peaks were recorded as the glass transition temperatures.

### Miscibility Evaluation for Adhesive Members

The miscibility evaluation was performed through the naked eyes on the samples each having the thickness of about 500 μm, manufactured to evaluate the storage moduli, the loss tangents, and the glass transition temperatures. In Table 2, “O” refers to being uniformly (e.g., substantially uniformly) optically transparent. In Table 2, “X” refers to being non-uniformly (e.g., substantially non-uniformly) transparent, and refers to that at least a portion is optically opaque.

### 180° Peel Strength Evaluation for Adhesive Members

Each of the resin compositions according to Examples and Comparative Examples was applied using a bar coater in a thickness of about 50 μm onto soda-lime glass (produced by Central Glass Co., Ltd.) having a size of about 26 mm×about 76 mm. Light was emitted onto the soda-lime glass coated with the resin composition by using LED lamps having peaks at wavelengths of about 365 nm and about 395 nm so that total amounts of the light reached about 800 mJ/cm² and about 400 mJ/cm², respectively. A PET film (A4360, produced by TOYOBO Co., Ltd., thickness: about 50 μm) having a size of about 20 mm×about 150 mm was provided on the resin composition irradiated with the light, and was bonded by applying a bonding pressure of about 0.15 megapascal (MPa). A sample was obtained by emitting light onto the PET film by using the LED lamp having the peak at the wavelength of about 395 nm after the bonding so that the total amount of the light reached about 4,000 mJ/cm².

The measurement of the peel strength was performed on the obtained sample under an environment having room temperature of about 25° C., at a speed of about 300 millimeter per minute (mm/min) by using a universal testing machine (produced by Instron Corporation, 5965 type or kind) so that a peel angle was about 180°. Average values for about 50 mm peeling were obtained, and the peel strength per width of about 25 mm obtained by multiplying each of the obtained values by about 1.25 was recorded in Table 2.

TABLE 2

| | Comparative | | | | | Comparative | Comparative |
|---|---|---|---|---|---|---|---|
| | Example | Example | Example | Example | Example | Example | Example |
| | 2-1 | 2-2 | 2-3 | 2-4 | 2-5 | 2-6 | 2-7 |
| Miscibility | ◯ | ◯ | ◯ | ◯ | ◯ | X | ◯ |
| Storage Modulus | 0.10 | 0.07 | 0.04 | 0.08 | 0.07 | 0.03 | 0.10 |
| [−20° C., MPa] | | | | | | | |
| Loss Tangent | 1.92 | 2.04 | 2.25 | 2.03 | 2.04 | 2.34 | 1.92 |
| [tan δ, −20° C.] | | | | | | | |
| Glass | −40 | −42 | −45 | −42 | −42 | −47 | −40 |
| Transition | | | | | | | |
| Temperature | | | | | | | |
| [° C.] | | | | | | | |
| 180° Peel | 870 | 600 | 330 | 620 | 300 | 230 | 1100 |
| Strength | | | | | | | |
| [25° C., | | | | | | | |
| gf/25 mm] | | | | | | | |

Referring to Table 2, it may be seen that each of the adhesive members according to Examples 2-2 to 2-5 was uniformly (e.g., substantially uniformly) optically transparent and has the loss tangent of about (e.g., at least) 2.0 or more and the storage modulus of (e.g., at most) about 1 MPa or less, each of which was measured by the dynamic viscoelasticity measurement in the shear mode at the frequency of about 1 Hz and at the temperature of about −20° C. It may be also seen that the adhesive members according to Examples 2-2 to 2-5 each have the 180° peel strength of (e.g., at least) about 300 gf/25 mm or more at the temperature of about 25° C. It may be seen that the adhesive members according to Examples 2-2 to 2-5 each have a glass transition temperature of about −46° C. to about −39° C.

The adhesive members according to Examples 2-2 to 2-5 were made by photocuring the resin compositions according to Examples 1-2 to 1-5 in Table 1, respectively, and correspond to adhesive members according to one or more embodiments. Accordingly, it may be ascertained that the adhesive member made from the resin composition according to one or more embodiments would exhibit excellent or suitable flexibility and excellent or suitable adhesion. It may be ascertained that the adhesive member made from the resin composition according to one or more embodiments would exhibit high adhesion and also exhibit a characteristic suitable for a flexible display device.

Referring to Table 2, it may be seen that the adhesive member according to Comparative Example 2-1 has a loss tangent of less than (e.g., at most) about 2.0 as measured by the dynamic viscoelasticity measurement in the shear mode at the frequency of about 1 Hz and at the temperature of about −20° C. The adhesive member according to Comparative Example 2-1 was made by curing the resin composition according to Comparative Example 1-1 in Table 1, and as described herein, the resin composition according to Comparative Example 1-1 includes less than (e.g., at most) about 5 wt % of the organopolysiloxane. Accordingly, the adhesive member according to Comparative Example 2-1 exhibits a poor bending characteristic, and the adhesive member according to Comparative Example 2-1 having the poor bending characteristic is not suitable for the flexible display device.

It may be seen that, in the adhesive member according to Comparative Example 2-6, at least a portion thereof is optically opaque, and the 180° peel strength thereof at the temperature of about 25° C. is less than (e.g., at most) about 300 gf/25 mm. The adhesive member according to Comparative Example 2-6 was made by curing the resin composition according to Comparative Example 1-6 in Table 1, and as described herein, the resin composition according to Comparative Example 1-6 includes the excess organopolysiloxane. Accordingly, it may be ascertained that the resin composition according to Comparative Example 1-6 including the excess organopolysiloxane is not good or suitable in optical transparency and has low adhesion after the curing.

Referring to Table 2, it may be ascertained that the adhesive member according to Comparative Example 2-7 has a loss tangent of less than (e.g., at most) about 2.0 as measured by the dynamic viscoelasticity measurement in the shear mode at the frequency of about 1 Hz and at the temperature of about −20° C., and has a relatively very high 180° peel strength at the temperature of about 25° C. The adhesive member according to Comparative Example 2-7 was made by curing the resin composition according to Comparative Example 1-7 in Table 1, and as described herein, the resin composition according to Comparative Example 1-7 does not include the organopolysiloxane. Accordingly, the adhesive member according to Comparative Example 2-7 exhibits a poor bending characteristic and exhibits excessively (or substantially) high adhesion, and the adhesive member according to Comparative Example 2-7, which exhibits the poor bending characteristic and the excessively (or substantially) high adhesion, is not suitable for the flexible display device.

A display device according to one or more embodiments may include an adhesive member arranged between a display panel and a window, and the adhesive member may include a polymer derived from a resin composition according to one or more embodiments. The adhesive member may be made by curing the resin composition according to one or more embodiments.

The resin composition according to one or more embodiments may include a monofunctional (meth)acrylate monomer, an organopolysiloxane, and a radical polymerization initiator. Accordingly, the resin composition according to one or more embodiments may exhibit a low-viscosity characteristic before the curing, and exhibit excellent or suitable flexibility and excellent or suitable reliability of adhesion after the curing (e.g., once cured). The adhesive member made from the resin composition according to one or more embodiments, and the display device including the adhesive member may exhibit excellent or suitable reliability.

The resin composition according to one or more embodiments may include the organopolysiloxane to exhibit the low-viscosity characteristic.

The adhesive member according to one or more embodiments may include the polymer derived from the resin composition according to one or more embodiments to exhibit the excellent or suitable flexibility and the excellent or suitable reliability of adhesion.

The display device according to one or more embodiments may include the adhesive member according to one or more embodiments to exhibit the excellent or suitable reliability.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Although one or more embodiments of the present disclosure have been described, it is understood that the present disclosure should not be limited to these embodiments. Rather, one or more suitable changes and modifications can be made by one ordinary skilled in the art within the spirit and scope of the present disclosure as hereinafter claimed.

Therefore, the technical scope of the disclosure is not limited to the contents described in the detailed description of the specification, but should be determined by the following claims and equivalents thereof.

What is claimed is:

1. A resin composition comprising:
at least one monofunctional (meth)acrylate monomer;
an organopolysiloxane; and
at least one photoinitiator comprising a radical polymerization initiator,
wherein the resin composition has a shear viscosity of about 5 millipascal second (mPa·s) to about 50 mPa·s as measured at a temperature of about 25° C.,
wherein the resin composition has a storage modulus of at most about 1 megapascal (MPa) as measured by a dynamic viscoelasticity measurement in a shear mode at a frequency of about 1 hertz (Hz) and at a temperature of about −20° C. once photocured,
wherein the resin composition has a loss tangent (tan δ) of at least about 2.0 as measured by the dynamic viscoelasticity measurement once photocured, and
wherein the resin composition is optically transparent once photocured.

2. The resin composition of claim 1, wherein an amount of the organopolysiloxane is at least about 5 wt % and less than about 35 wt % based on a total of 100 wt % of the resin composition.

3. The resin composition of claim 1, wherein a weight average molecular weight of the organopolysiloxane is at least about 500 and less than about 50,000.

4. The resin composition of claim 1, wherein the organopolysiloxane excludes any radical polymerizable group.

5. The resin composition of claim 1, wherein the resin composition has a 180° peel strength of at least about 300 gram force per 25 millimeter (gf/25 mm) for at least one of a polymer substrate or a glass substrate at a temperature of about 25° C. once photocured.

6. The resin composition of claim 1, wherein the resin composition excludes any solvent.

7. The resin composition of claim 1, wherein the monofunctional (meth)acrylate monomer comprises at least one of 4-hydroxybutyl acrylate (4-HBA), 2-ethylhexyl acrylate (2-EHA), tetrahydrofurfuryl acrylate (THF-A), or 2-ethylhexyl-diglycol acrylate (EHDG-AT).

8. The resin composition of claim 1, wherein an amount of the monofunctional (meth)acrylate monomer is about 60 wt % to about 85 wt % based on a total of 100 wt % of the resin composition.

9. The resin composition of claim 1, further comprising a urethane (meth)acrylate oligomer.

10. The resin composition of claim 1, further comprising a silane coupling agent.

11. The resin composition of claim 1, wherein the resin composition has a glass transition temperature of about −46° C. to about −39° C. once photocured.

12. The resin composition of claim 1, wherein the resin composition is provided by an inkjet printing method or a dispensing method.

13. An adhesive member, the adhesive member having
a storage modulus of at most about 1 MPa as measured by a dynamic viscoelasticity measurement in a shear mode at a frequency of about 1 Hz and at a temperature of about −20° C., and
a loss tangent (tan δ) of at least about 2.0 as measured by the dynamic viscoelasticity measurement,
the adhesive member being optically transparent and comprising a polymer derived from a resin composition,
wherein the resin composition comprises:
at least one monofunctional (meth)acrylate monomer;
an organopolysiloxane; and
at least one photoinitiator comprising a radical polymerization initiator, and
wherein the resin composition has a shear viscosity of about 5 mPa·s to about 50 mPa·s as measured at a temperature of about 25° C.

14. The adhesive member of claim 13, wherein an amount of the organopolysiloxane is at least about 5 wt % and less than about 35 wt % based on a total of 100 wt % of the resin composition.

15. The adhesive member of claim 13, wherein a weight average molecular weight of the organopolysiloxane is at least about 500 and less than about 50,000.

16. The adhesive member of claim 13, wherein the organopolysiloxane excludes any radical polymerizable group.

17. The adhesive member of claim 13, wherein the adhesive member has a 180° peel strength of at least about 300 gf/25 mm for at least one of a polymer substrate or a glass substrate at a temperature of about 25° C.

18. The adhesive member of claim 13, wherein the monofunctional (meth)acrylate monomer comprises at least one of 4-hydroxybutyl acrylate (4-HBA), 2-ethylhexyl acrylate (2-EHA), tetrahydrofurfuryl acrylate (THF-A), or 2-ethylhexyl-diglycol acrylate (EHDG-AT).

19. The adhesive member of claim 13, wherein an amount of the monofunctional (meth)acrylate monomer is about 60 wt % to about 85 wt % based on a total of 100 wt % of the resin composition.

20. The adhesive member of claim 13, wherein the resin composition further comprises a urethane (meth)acrylate oligomer.

21. The adhesive member of claim 13, wherein the resin composition further comprises a silane coupling agent.

22. The adhesive member of claim 13, wherein the adhesive member has a glass transition temperature of about-46° C. to about −39° C.

23. An electronic device comprising:
a display panel;
a window on the display panel; and
an adhesive member having a storage modulus of at most about 1 MPa as measured by a dynamic viscoelasticity measurement in a shear mode at a frequency of about 1 Hz and at a temperature of about −20° C., and
a loss tangent (tan δ) of at least about 2.0 as measured by the dynamic viscoelasticity measurement,
the adhesive member being optically transparent comprising a polymer derived from a resin composition, and being between the display panel and the window,
wherein the resin composition comprises:
at least one monofunctional (meth)acrylate monomer;
an organopolysiloxane; and
at least one photoinitiator comprising a radical polymerization initiator, and
wherein the resin composition has a shear viscosity of about 5 mPa·s to about 50 mPa·s as measured at a temperature of about 25° C.

24. The electronic device of claim 23, wherein an amount of the organopolysiloxane is at least about 5 wt % and less than about 35 wt % based on a total of 100 wt % of the resin composition.

25. The electronic device of claim 23, wherein a weight average molecular weight of the organopolysiloxane is at least about 500 and less than about 50,000.

26. The electronic device of claim 23, wherein the organopolysiloxane excludes any radical polymerizable group.

27. The electronic device of claim 23, wherein the adhesive member has a 180° peel strength of at least about 300 gf/25 mm for at least one of a polymer substrate or a glass substrate at a temperature of about 25° C.

28. The electronic device of claim 23, wherein the monofunctional (meth)acrylate monomer comprises at least one of 4-hydroxybutyl acrylate (4-HBA), 2-ethylhexyl acrylate (2-EHA), tetrahydrofurfuryl acrylate (THF-A), or 2-ethylhexyl-diglycol acrylate (EHDG-AT).

29. The electronic device of claim 23, wherein the resin composition further comprises a urethane (meth)acrylate oligomer.

30. The electronic device of claim 23, wherein the adhesive member has a glass transition temperature of about −46° C. to about −39° C.

31. The electronic device of claim 23, further comprising an input sensing part between the display panel and the window,
wherein the adhesive member is between the display panel and the input sensing part, or between the input sensing part and the window.
